(19) United States
(12) Patent Application Publication
(10) Pub. No.: US 2023/0272517 A1
(43) Pub. Date: Aug. 31, 2023

(54) DEPOSITION MASK AND METHOD FOR MANUFACTURING DEPOSITION MASK

(71) Applicant: Dai Nippon Printing Co., Ltd., Tokyo (JP)

(72) Inventors: Yuji ANZAI, Tokyo (JP); Chikao IKENAGA, Tokyo (JP); Isao INOUE, Tokyo (JP)

(73) Assignee: Dai Nippon Printing Co., Ltd., Tokyo (JP)

(21) Appl. No.: 18/163,901

(22) Filed: Feb. 3, 2023

Related U.S. Application Data
(63) Continuation of application No. PCT/JP2021/029269, filed on Aug. 6, 2021.

(30) Foreign Application Priority Data
Aug. 6, 2020 (JP) 2020-134165

(51) Int. Cl. C23C 14/04; C23C 14/24

(52) U.S. Cl. CPC C23C 14/042; C23C 14/24; H10K 71/166

(57) ABSTRACT

A deposition mask includes a metal plate including first and second surfaces located opposite each other, through holes bored through the metal plate from the first surface to the second surface, and a flat region located between two through holes adjacent to each other in a case where the deposition mask is seen from the second surface side. The through holes are arrayed in a staggered arrangement in first and second directions in planar view. The flat region includes first and second flat regions located at first and second sides, respectively, of a first center line. The first center line passes through center points of two through holes adjacent to each other in the first direction. The first and second flat regions include portions in which dimensions of the first and second flat regions in the first direction increase away from the first center line, respectively.

### CROSS REFERENCES TO RELATED APPLICATIONS

The present application is a continuation application of PCT/JP2021/029269, filed Aug. 6, 2021, which claims priority to Japanese Patent Application No. 2020-134165, filed Aug. 6, 2020. The contents of these applications are incorporated herein by reference in their entirety.

### BACKGROUND

### 1. Field

Embodiments of the present disclosure relates to a deposition mask and a method for manufacturing a deposition mask.

### 2. Description of the Related Art

It is preferable that a display device that is used in a portable device such as a smartphone or a tablet PC be high in definition and, for example, have a pixel density of 400 ppi or higher. In the field of portable devices too, there has been a growing demand for compatibility with ultrahigh definition (UHD), and in this case, it is preferable that a display device have a pixel density of, for example, 800 ppi or higher.

Of display devices, organic EL display devices have attracted attention because of their high responsivity, low power consumption, and high contrast. As a method for forming pixels of an organic EL display device, there has been known a method for forming pixels in a desired pattern using a deposition mask having formed therein through holes arrayed in a desired pattern. Specifically, first, the deposition mask is combined with a substrate for use in the organic EL display device. Then, a deposited material containing an organic material is made to adhere to the substrate via the through holes of the deposition mask. By executing such a deposition step, pixels each having a deposited layer containing the deposited material can be formed on top of the substrate in a pattern corresponding to the pattern of the through holes of the deposition mask.

As a method for manufacturing a mask, there has been known a method for forming through holes in a metal plate by etching involving the use of a photolithography technique. For example, first, a first surface resist layer is formed on a first surface of the metal plate, and a second surface resist layer is formed on a second surface of the metal plate. Next, by etching regions on the first surface of the metal plate not covered with the first surface resist layer, first concave portions are formed in the first surface of the metal plate. After that, by etching regions on the second surface of the metal plate not covered with the second surface resist layer, second concave portions are formed in the second surface of the metal plate. In so doing, by performing etching so that the first concave portions and the second concave portions communicate with each other, through holes bored through the metal plate can be formed.
Japanese Patent Application Publication No. 2014-148745 is an example of related art.

### SUMMARY

In a deposition step, a portion of the deposited material traveling from a deposition source to the deposition mask migrates in a direction inclined with respect to a direction normal to the metal plate constituting the deposition mask. The deposition material that migrates in the direction inclined with respect to the direction normal to the metal plate tends to adhere to wall surfaces of the through holes of the deposition mask without passing through the through holes. For this reason, the thickness of a deposited layer that is constituted by the deposited material adhering to the substrate tends to become gradually smaller toward the wall surfaces of the through holes. Such a phenomenon in which the adhesion of the deposited material to the substrate is inhibited by the wall surfaces of the through holes is also referred to as “shadow”.

In an embodiment of the present disclosure, a deposition mask including two or more through holes includes a metal plate including a first surface and a second surface located opposite the first surface, the through holes each bored through the metal plate from the first surface to the second surface, and a flat region located between two of the through holes adjacent to each other in a case where the deposition mask is seen from the second surface side. The through holes are arrayed in a staggered arrangement in a first direction and a second direction in planar view. The flat region includes a first flat region located at a first side of a first center line and a second flat region located at a second side of the first center line. The first center line passes through center points of two of the through holes adjacent to each other in the first direction. The first flat region includes a portion in which a dimension of the first flat region in the first direction increases away from the first center line. The second flat region includes a portion in which a dimension of the second flat region in the first direction increases away from the first center line.

The embodiment of the present disclosure makes it possible to reduce the occurrence of a shadow while reducing the occurrence of a defect such as a deformation in a deposition mask.

### BRIEF DESCRIPTION OF THE DRAWINGS

FIG. 1 is a plan view showing an example of an organic EL display device.

FIG. 2 is a cross-sectional view of the organic EL display device as taken along line II-II in FIG. 1.

FIG. 3 is a diagram showing a deposition apparatus including a deposition mask device according to an embodiment of the present disclosure.

FIG. 4 is a plan view showing an example of the deposition mask device.

FIG. 5A is a plan view showing an example of an effective region of a deposition mask of the deposition mask device of FIG. 4 as seen from the second surface side.

FIG. 5B is a plan view showing through regions of through holes of FIG. 5A.

FIG. 6 is an example of a cross-sectional view of the deposition mask as taken along line A-A in FIG. 5A.

FIG. 7 is an example of a cross-sectional view of the deposition mask as taken along line B-B in FIG. 5A.

FIG. 8 is an example of a cross-sectional view of the deposition mask as taken along line C-C in FIG. 5A.

FIG. 9 is a plan view showing first and second flat regions of FIG. 5A.

FIG. 10 is a schematic view for explaining overall an example of a method for manufacturing a deposition mask.

FIG. 11 is a diagram showing a step of forming a first surface resist layer and a second surface resist layer on a metal plate.

FIG. 12 is a diagram showing a step of patterning the first surface resist layer and the second surface resist layer.

FIG. 13 is a diagram showing a first surface etching step.

FIG. 14 is a diagram showing a second surface etching step.

FIG. 15 is a diagram showing the second surface etching step.

FIG. 16 is a plan view showing examples of first and second flat regions of a deposition mask.

FIG. 17 is a plan view showing examples of first and second flat regions of a deposition mask.

FIG. 18 is a plan view showing an example of an effective region of a deposition mask as seen from the second surface side.

FIG. 19 is an example of a cross-sectional view of the deposition mask as taken along line D-D in FIG. 18.

FIG. 20 is a plan view showing first and second flat regions of FIG. 18.

FIG. 21 is a cross-sectional view showing an example of a metal plate provided with a second surface resist layer that has been patterned.

FIG. 22 is a diagram showing an example of the second surface etching step.

FIG. 23 is a diagram showing an example of a first surface processing step.

FIG. 24 is a diagram showing configurations of deposition masks in examples and evaluation results.

### DESCRIPTION OF THE EMBODIMENTS

In the present specification and the present drawings, unless otherwise specifically described, terms, such as “substrate” “base material”, “plate”, “sheet”, and “film”, that mean a matter forming the basis of a certain component are not distinguished from one another solely on the basis of the difference in designation.

In the present specification and the present drawings, unless otherwise specifically described, shapes and geometric conditions, terms, such as “parallel” and “orthogonal”, that specify the extents of the shapes and the geometric conditions, and values, such as lengths and angles, that specify the extents of the shapes and the geometric conditions are not bound by the strict sense but are construed with the inclusion of a range of extents to which similar functions may be expected.

In the present specification and the present drawings, unless otherwise specifically described, cases where a certain component such as a certain member or a certain region is “on top of” or “under”, “on the upper side” or “on the lower side”, or “above” or “below” another component such as another member or another region encompass cases where a certain component is in direct contact with another component. Furthermore, the cases also encompass cases where a different component is included between a certain component and another component, i.e. cases where a certain component is in indirect contact with another component. Further, unless otherwise specifically described, the words and phrases such as “on top of”, “on the upper side”, “above”, “under”, “on the lower side”, and “below” may be turned upside down in meaning.

In the present specification and the present drawings, unless otherwise specifically described, identical components or components having similar functions may be assigned identical or similar signs, and a repeated description of such components may be omitted. For convenience of explanation, dimensional ratios in the drawings may be different from actual ratios, or some components may be omitted from the drawings.

In the present specification and the present drawings, unless otherwise specifically described, an embodiment of the present specification may be combined with another embodiment unless a contradiction arises. Other embodiments may be combined with each other unless a contradiction arises.

In the present specification and the present drawings, unless otherwise specifically described, in a case where multiple steps are disclosed regarding a method such as a manufacturing method, another step that is not disclosed may be executed between steps that are disclosed. The steps that are disclosed may be executed in any order unless a contradiction arises.

In the present specification and the present drawings, unless otherwise specifically described, a range expressed by the preposition “to” includes a numerical value placed before “to” and a numerical value placed after “to”. For example, the range of numerical values defined by the expression “34 to 38 mass %” is identical to the range of numerical values defined by the expression “34 mass % or higher and 38 mass % or lower”.

An embodiment of the present disclosure is described in detail below with reference to the drawings. It should be noted that the embodiment to be described below is one example among embodiments of the present disclosure, and the present disclosure should not be construed only within the limits of these embodiments.

A first aspect of the present disclosure is directed to a deposition mask including two or more through holes, the deposition mask including:

a metal plate including a first surface and a second surface located opposite the first surface;

the through holes each bored through the metal plate from the first surface to the second surface; and

a flat region located between two of the through holes adjacent to each other in a case where the deposition mask is seen from the second surface side,

wherein

the through holes are arrayed in a staggered arrangement in a first direction and a second direction in planar view,

the flat region includes a first flat region located at a first side of a first center line and a second flat region located at a second side of the first center line,

the first center line passes through center points of two of the through holes adjacent to each other in the first direction,

the first flat region includes a portion in which a dimension of the first flat region in the first direction increases away from the first center line, and

the second flat region includes a portion in which a dimension of the second flat region in the first direction increases away from the first center line.

A second aspect of the present disclosure may be directed to the deposition mask according to the first aspect, wherein the first flat region and the second flat region may be contiguous to each other.

A third aspect of the present disclosure may be directed to the deposition mask according to the first aspect, wherein the first flat region and the second flat region may be noncontiguous to each other.

A fourth aspect of the present disclosure may be directed to the deposition mask according to each of the first to third aspects, wherein in a case where the deposition mask is seen from the second surface side, two of the through holes adjacent to each other in the second direction may be connected to each other.

In a fifth aspect of the present disclosure, the deposition mask according to each of the first to third aspects may further include a third flat region located between two of the through holes adjacent to each other in the second direction in a case where the deposition mask is seen from the second surface side.

A sixth aspect of the present disclosure may be directed to the deposition mask according to the first aspect, wherein

the first flat region and the second flat region may be contiguous to each other, and in a case where the deposition mask is seen from the second surface side, two of the through holes adjacent to each other in the second direction may be connected to each other, and

a dimension in the first direction of a portion of the first flat region that overlaps the first center line may be 0.90 time or less as great as a distance in the first direction between ends of two contours of the first flat region, the two contours facing the through holes in the first direction.

A seventh aspect of the present disclosure may be directed to the deposition mask according to the first or sixth aspect, wherein

the first flat region and the second flat region may be contiguous to each other, and in a case where the deposition mask is seen from the second surface side, two of the through holes adjacent to each other in the second direction may be connected to each other,

a dimension in a third direction of a portion of the flat region that overlaps a third center line may be 1.00 time or less as great as a distance in the third direction between ends of two contours of the flat region, the two contours facing the through holes in the third direction,

the third direction may be orthogonal to the first direction, and

the third center line may pass through center points of two of the through holes adjacent to each other in the first direction and extend in the third direction.

An eighth aspect of the present disclosure may be directed to the deposition mask according to each of the first to third aspects, wherein

each of the through holes may include a first concave portion including a first wall surface located at the first surface and a second concave portion including a second wall surface located at the second surface, the second concave portion being connected to the first concave portion, and

the second wall surface may include a portion that becomes gradually closer to a center point of the through hole as the portion extends from the second surface toward the first surface.

A ninth aspect of the present disclosure may be directed to the deposition mask according to each of the first to eighth aspects, wherein the flat region may exhibit a pixel value greater than or equal to a reference value in a case where the deposition mask is observed with a laser microscope from the second surface side.

A tenth aspect of the present disclosure may be directed to the deposition mask according to each of the first to ninth aspects, wherein a thickness of the flat region may be equal to a thickness of the metal plate.

An eleventh aspect of the present disclosure may be directed to the deposition mask according to each of the first to tenth aspects, wherein the metal plate may have a thickness of 30 μm or less.

A twelfth aspect of the present disclosure is directed to a method for manufacturing a deposition mask including two or more through holes, the method including:

a first surface processing step of forming, in a first surface of a metal plate, a first concave portion including a first wall surface; and

a second surface etching step of etching a region of a second surface of the metal plate with an etchant and forming, in the second surface, a second concave portion including a second wall surface, the second surface being located opposite the first surface, the region being not covered with a second surface resist layer,

wherein

each of the through holes includes the first concave portion and the second concave portion, the second concave portion being connected to the first concave portion,

the second surface etching step is executed so that a flat region remains between two of the through holes adjacent to each other in a case where the deposition mask in seen from the second surface side,

the through holes are arrayed in a staggered arrangement in a first direction and a second direction in planar view,

the flat region includes, between two of the through holes adjacent to each other in the first direction, a first flat region located at a first side of a first center line and a second flat region located at a second side of the first center line,

the first center line passes through center points of two of the through holes adjacent to each other in the first direction,

the first flat region includes a portion in which a dimension of the first flat region in the first direction increases away from the first center line, and

the second flat region includes a portion in which a dimension of the second flat region in the first direction increases away from the first center line.

A thirteenth aspect of the present disclosure is directed to the method according to the twelfth aspect, wherein the second surface etching step may be executed so that the first flat region and the second flat region are contiguous to each other.

A fourteenth aspect of the present disclosure is directed to the method according to the twelfth aspect, wherein the second surface etching step may be executed so that the first flat region and the second flat region are noncontiguous to each other.

A fifteenth aspect of the present disclosure is directed to the method according to each of the twelfth to fourteenth aspects, wherein the second surface etching step may be executed so that in a case where the deposition mask is seen from the second surface side, two of the through holes adjacent to each other in the second direction are connected to each other.

A sixteenth aspect of the present disclosure is directed to the method according to each of the twelfth to fourteenth aspects, wherein the second surface etching step may be executed so that in a case where the deposition mask is seen from the second surface side, two of the through holes adjacent to each other in the second direction are not connected to each other.

A seventeenth aspect of the present disclosure is directed to the method according to each of the twelfth to sixteenth aspects, wherein

the second surface resist layer may include a first region corresponding to the first flat region and a second region corresponding to the second flat region,

the first region may include a portion in which a dimension of the first region in the first direction increases away from the first center line, and

the second region may include a portion in which a dimension of the second region in the first direction increases away from the first center line.

An eighteenth aspect of the present disclosure is directed to the method according to each of the twelfth to seventeenth aspects, wherein the flat region may exhibit a pixel value greater than or equal to a reference value in a case where the deposition mask is observed with a laser microscope from the second surface side.

A nineteenth aspect of the present disclosure is directed to the method according to each of the twelfth to eighteenth aspects, wherein the metal plate may have a thickness of 30 μm or less.

An embodiment of the present disclosure is described in detail below with reference to the drawings. The embodiment to be described below is one example among embodiments of the present disclosure, and the present disclosure should not be construed only within the limits of these embodiments.

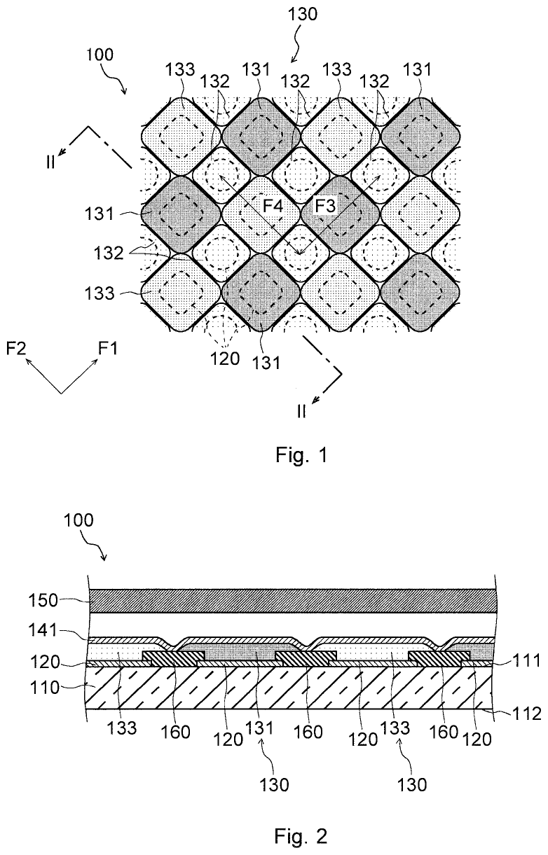

FIG. 1 is a plan view showing an example of an organic EL display device 100. FIG. 2 is a cross-sectional view of the organic EL display device 100 as taken along line II-II in FIG. 1. FIG. 1 omits to illustrate a second electrode layer 141 and a sealing substrate 150.

As shown in FIGS. 1 and 2, the organic EL display device 100 may include a substrate 110, first electrode layers 120 located on a first surface 111 of the substrate 110, first, second, and third organic layers 131, 132, and 133 located on top of the first electrode layers 120, and a second electrode layer 141 located on top of the first, second, and third organic layers 131, 132, and 133.

The substrate 110 may be a plate member having insulation properties. The substrate 110 preferably has transparency that allows passage of light. The substrate 110 contains, for example, glass.

The first electrode layers 120 contain an electrical conducting material. For example, the first electrode layers 120 may contain a metal, an electrical conducting metal oxide, or other inorganic materials. The first electrode layers 120 may contain a transparent and electrical conducting metal oxide such as indium tin oxide.

As indicated by dotted lines in FIG. 1, the first electrode layers 120 may be arranged along a first array direction F1 and a second array direction F2 in planar view. As shown in FIG. 1, the second array direction F2 may be a direction orthogonal to the first array direction F1.

The first, second, and third organic layers 131, 132, and 133 may be layers containing an organic semiconductor material. The first, second, and third organic layers 131, 132, and 133 may be luminescent layers. For example, the first, second, and third organic layers 131, 132, and 133 may be red, green, and blue luminescent layers, respectively. A region including one first electrode layer 120, one deposited layer, and the second electrode layer 141 in planar view may constitute a unit structure such as one pixel of the organic EL display device 100.

As shown in FIG. 1, the first, second, and third organic layers 131, 132, and 133 may be arrayed so that organic layers of an identical type are not adjacent to each other in the first array direction F1 or the second array direction F2. For example, the first, second, and third organic layers 131, 132, and 133 may be arrayed in the first array direction F1 and the second array direction F2 so that a second organic layer 132 is located between two first organic layers 131 and a second organic layer 132 is located between two third organic layers 133. In this case, with attention focused on the second organic layers 132, the second organic layers 132 are arranged in a zigzag manner in positions shifted by a distance half as long as an array pitch F3 in the first array direction F1 and shifted by a distance half as long as an array pitch F4 in the second array direction F2. Such an array is also referred to as “staggered arrangement”.

Each of the first, second, and third organic layers 131, 132, and 133 may be a deposited layer formed by causing a deposited material to adhere to the substrate 110 via through holes of a deposition mask corresponding to a pattern of that organic layer.

The second electrode layer 141 may contain an electrical conducting material such as a metal. Possible examples of materials of which the second electrode layer 141 is made include platinum, gold, silver, copper, iron, tin, chromium, aluminum, indium, lithium, sodium, potassium, calcium, magnesium, carbon, and alloys thereof.

Although not illustrated, the second electrode layer 141 may be formed so that there is a gap between second electrode layers 141 located on top of adjacent two of the organic layers 131, 132, and 133. Such a second electrode layer 141 may be formed by causing a deposited material to adhere to the substrate 110 via through holes of a deposition mask corresponding to a pattern of the second electrode layer 141.

As shown in FIG. 2, the organic EL display device 100 may include insulating layers 160 each located between adjacent two of the first electrode layers 120 in planar view. The insulating layers 160 may contain, for example, polyimide. The insulating layers 160 may overlap ends of the first electrode layers 120. In this case, dotted lines denoted by reference sign 120 indicate the outer edges of regions of the first electrode layers 120 not overlapped with the insulating layers 160. As shown in FIG. 1, the first, second, and third organic layers 131, 132, and 133 may spread so as to cover the first electrode layers 120 in planar view. The contours of the first, second, and third organic layers 131, 132, and 133 may surround the contours of the first electrode layers 120 in planar view.

As shown in FIG. 2, the organic EL display device 100 may include a sealing substrate 150 covering elements such as the organic layers 131, 132, and 133 over the substrate 110 at the first surface 111 of the substrate 110. The sealing substrate 150 can restrain water vapor or other substances from entering the organic EL display device 100 from outside the organic EL display device 100. This makes it possible to restrain the organic layers 131, 132, and 133 or other components from deteriorating due to moisture. The sealing substrate 150 contains, for example, glass.

Although not illustrated, the organic EL display device 100 may include hole injection and hole transport layers located between the first electrode layers 120 and the organic layers 131, 132, and 133. The organic EL display device 100 may include electron transport and electron injection layers located between the organic layers 131, 132, and 133 and the second electrode layer 141. As is the case with the organic layers 131, 132, and 133, each of the hole injection, hole transport, electron transport, and electron injection layers may be formed by causing a deposited material to adhere to the substrate 110 via through holes of a deposition mask corresponding to a pattern of that layer.

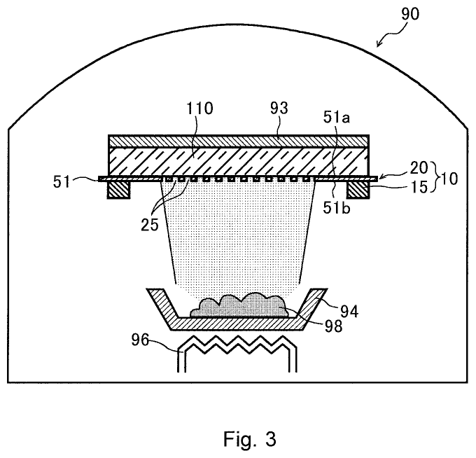

Next, a deposition apparatus 90 for forming layers such as the aforementioned organic layers 131, 132, and 133 of the organic EL display device 100 using a deposition method is described. As shown in FIG. 3, the deposition apparatus 90 may include a deposition source 94, a heater 96, and a deposition mask device 10 inside thereof. The deposition apparatus 90 may include exhaust means for bringing the interior of the deposition apparatus 90 into a vacuum atmosphere. The deposition source 94 is for example a crucible, and accommodates a deposited material 98 such as an organic luminescence material. The heater 96 heats the deposition source 94 to evaporate the deposited material 98 in a vacuum atmosphere. The deposition mask 10 is placed opposite the crucible 94.

The deposition mask device 10 includes at least one deposition mask 20. The deposition mask device 10 may include a frame 15 supporting the deposition mask 20. The frame 15 may support the deposition mask 20 while stretching the deposition mask 20 in a direction parallel with the plane of the deposition mask 20 so as to restrain the deposition mask 20 from warping.

As shown in FIG. 3, the deposition mask device 10 is placed in the deposition apparatus 90 so that the deposition mask 20 faces the substrate 110, which is a physical object to which the deposited material 98 is made to adhere. The deposition mask 20 includes a plurality of through holes 25 through which a portion of the deposited material 98 having flown from the deposition source 94 passes. In the following description, a surface of the deposition mask 20 located at the substrate 110 is referred to as “first surface 51a”, and a surface of the deposition mask 20 located opposite the first surface 51a is also referred to as “second surface 51b”.

As shown in FIG. 3, the deposition mask device 10 may include a magnet 93 disposed at a surface of the substrate 110 that faces away from the deposition mask 20. Providing the magnet 93 makes it possible to magnetically attract the deposition mask 20 toward the magnet 93. This makes it possible to reduce or eliminate a gap between the deposition mask 20 and the substrate 110. This makes it possible to reduce the occurrence of a shadow in a deposition step, and makes it possible to increase the dimensional accuracy and positional accuracy of deposited layers that are formed on the substrate 110.

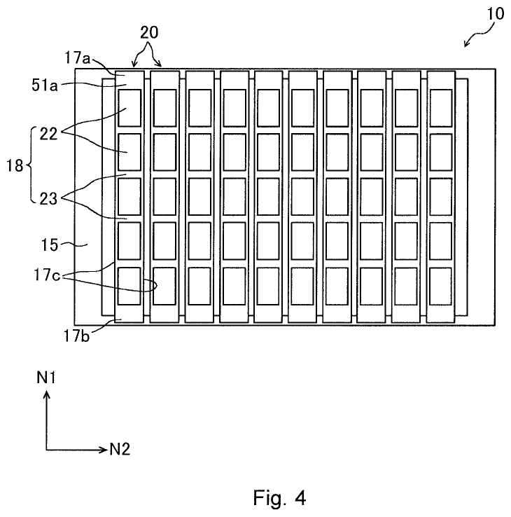

FIG. 4 is a plan view of the deposition mask device 10 as seen from the first surface 51a side of the deposition mask 20. As shown in FIG. 4, the deposition mask device 10 may include a plurality of deposition masks 20. Each of the deposition masks 20 may have the shape of a rectangle having a length direction and a width direction orthogonal to the length direction. A dimension of the deposition mask 20 in the length direction is larger than a dimension of the deposition mask 20 in the width direction. In the following description, the length direction is also referred to as “mask first direction,” and the width direction is also referred to as “mask second direction”. The plurality of deposition masks 20 may be arranged in the mask second direction N2. Ends 17a and 17b of each deposition mask 20 in the mask first direction N1 may be fixed to the frame 15, for example, by welding. Although not illustrated, the deposition mask device 10 may include a member that is fixed to the frame 15 and that partly overlaps a deposition mask 20 in a thickness direction of the deposition mask 20. Possible examples of such members include a member that extends in the mask second direction N2 and that supports a deposition mask 20, a member that overlaps a gap between two adjacent deposition masks 20, or other members.

As shown in FIG. 4, each of the deposition masks 20 may include two ends 17a and 17b overlapping the frame 15 and an intermediate portion 18 located between the ends 17a and 17b. The intermediate portion 18 may include at least one effective region 22 and a surrounding region 23 located around the effective region 22. As shown in FIG. 4, the intermediate portion 18 may include a plurality of effective regions 22 arrayed at predetermined spacings along the mask first direction N1. The surrounding region 23 may surround the plurality of effective regions 22.

In a case where a layer of the organic EL display device 100 is fabricated using a deposition mask 20, one effective region 22 may correspond to one display area of the organic EL display device 100. One effective region 22 may correspond to a plurality of display areas. Although not illustrated, a plurality of effective regions 22 may be arrayed at predetermined spacings in the mask second direction N2 too.

The effective regions 22 may have rectangular contours in planar view. The effective regions 22 may have variously shaped contours according to the shape of a display area of the organic EL display device 100. For example, the effective regions 22 may have circular contours.

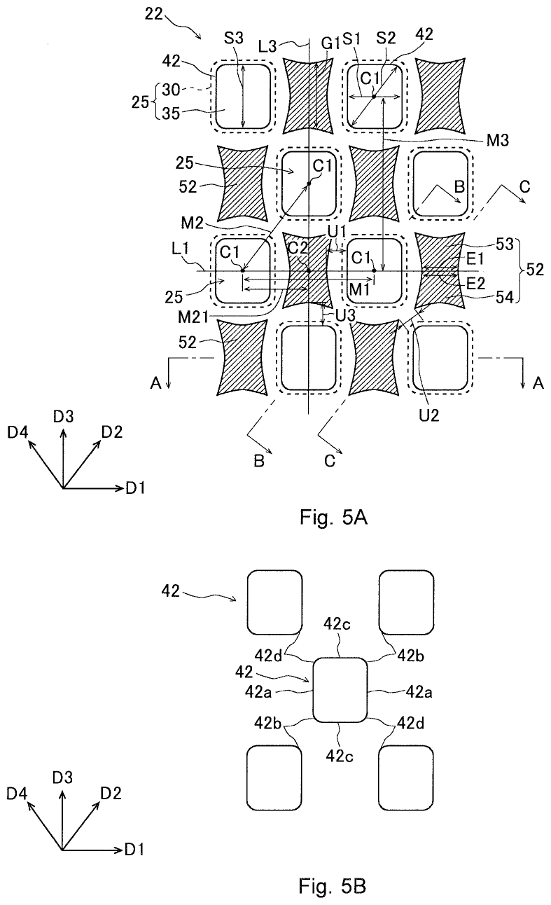

Next, an effective region 22 is described in detail. FIG. 5A is a plan view showing an example of an effective region 22 of a deposition mask 20 as seen from the second surface 51b side. The present embodiment illustrates an example in which, as shown in FIG. 5A, a deposition mask 20 has through holes 25 arrayed in a staggered arrangement. Such a deposition mask 20 may be used for forming a staggered arrangement of deposited layers such as the aforementioned second organic layers 132.

An effective region 22 of a deposition mask 20 includes a metal plate 51 including a first surface 51a and a second surface 51b and a plurality of through holes 25 bored through the metal plane 51 from the first surface 51a to the second surface 51b. As shown in FIG. 5A, the through holes 25 may be arranged in a first direction D1 and a second direction D2 in planar view. The second direction D2 may be a direction orthogonal to the first direction D1. As is the case with the deposited layers, the through holes 25 may be arrayed in a staggered arrangement in planar view. Specifically, as shown in FIG. 5A, a distance M21 in the first direction D1 between center points C1 of two through holes 25 adjacent to each other in the second direction D2 may be ½ of a first center-to-center distance M1 between center points C1 of two through holes 25 adjacent to each other in the first direction D1.

In FIG. 5A, reference sign D3 denotes a third direction D3 orthogonal to the first direction D1. Reference sign D4 denotes a fourth direction D4 that is symmetrical with the second direction D2 about the third direction D3. As shown in FIG. 5A, the plurality of through holes 25 may be arranged in the fourth direction D4. Although not illustrated, the distance in the first direction D1 between center points C1 of two through holes 25 adjacent to each other in the fourth direction D4 too may be ½ of the first center-to-center distance M1.

A second center-to-center distance M2 between the center points C1 of two through holes 25 adjacent to each other in the second direction D2 may be equal to the first center-to-center distance M1, may be greater than the first center-to-center distance M1, or may be less than the first center-to-center distance M1.

A third center-to-center distance M3 between center points C1 of two through holes 25 adjacent to each other in the third direction D3 may be greater than the first center-to-center distance M1. M3/M1, which is the ratio of the third center-to-center distance M3 to the first center-to-center distance M1, may for example be higher than or equal to 1.1, higher than or equal to 1.3, or higher than or equal to 1.5. M3/M1 may for example be lower than or equal to 1.7, lower than or equal to 2.0, or lower than or equal to 2.5. M3/M1 may fall within a range defined by a first group consisting of 1.1, 1.3, and 1.5 and/or a second group consisting of 1.7, 2.0, and 2.5. M3/M1 may fall within a range defined by a combination of any one of the values included in the aforementioned first group and any one of the values included in the aforementioned second group. M3/M1 may fall within a range defined by a combination of any two of the values included in the aforementioned first group. M3/M1 may fall within a range defined by a combination of any two of the values included in the aforementioned second group. M3/M1 may for example be higher than or equal to 1.1 and lower than or equal to 2.5, higher than or equal to 1.1 and lower than or equal to 2.0, higher than or equal to 1.1 and lower than or equal to 1.7, higher than or equal to 1.1 and lower than or equal to 1.5, higher than or equal to 1.1 and lower than or equal to 1.3, higher than or equal to 1.3 and lower than or equal to 2.5, higher than or equal to 1.3 and lower than or equal to 2.0, higher than or equal to 1.3 and lower than or equal to 1.7, higher than or equal to 1.3 and lower than or equal to 1.5, higher than or equal to 1.5 and lower than or equal to 2.5, higher than or equal to 1.5 and lower than or equal to 2.0, higher than or equal to 1.5 and lower than or equal to 1.7, higher than or equal to 1.7 and lower than or equal to 2.5, higher than or equal to 1.7 and lower than or equal to 2.0, or higher than or equal to 2.0 and lower than or equal to 2.5.

As shown in FIG. 5A, each of the through holes 25 includes a through region 42. The through region 42 is a region bored through the metal plate 51 in planar view. The through region 42 may be demarcated by light that passes through the through hole 25. For example, parallel light falls on one of the first and second surfaces 51a and 51b of the deposition mask 20 along a direction normal to the metal plate 51, passes through the through hole 25, and is emitted through the other of the first and second surfaces 51a and 51b. Then, a region occupied by the emitted light in a direction parallel with the plane of the metal plate 51 is employed as the through region 42 of the through hole 25. Alternatively, the through region 42 may be demarcated by observing the deposition mask 20 with a laser microscope.

FIG. 5B is a diagram for explaining the contours and arrangement of the through regions 42 of through holes 25 in planar view. As shown in FIG. 5B, the contours of the through region 42 of each of the through holes 25 include a pair of first contours 42a, a pair of third contours 42c, two second contours 42b each located between a first contour 42a and a third contour 42c, and two fourth contours 42d each located between a first contour 42a and a third contour 42c. In the first direction D1, the first contours 42a of two adjacent through holes 25 are opposite to each other. In the second direction D2, the second contours 42b of two adjacent through holes 25 are opposite to each other. In the fourth direction D4, the fourth contours 42d of two adjacent through holes 25 are opposite to each other.

Each of the first contours 42a may include a portion linearly extending in the third direction D3, or may include a curved portion. In a case where each of the first contours 42a includes a curved portion, the curvature of the curved portion of the first contour 42a may be greater than the curvature of each of the second contours 42b and the curvature of each of the fourth contours 42d.

Each of the third contours 42c may include a portion linearly extending in the first direction D1, or may include a curved portion. In a case where each of the third contours 42c includes a curved portion, the curvature of the curved portion of the third contour 42c may be greater than the curvature of each of the second contours 42b and the curvature of each of the fourth contours 42d.

Next, a region between through holes 25 is described. As shown in FIG. 5A, an effective region 22 of a deposition mask 20 may include flat regions 52 each located between two through holes 25 adjacent to each other in a case where the deposition mask 20 is seen from the second surface 51b side. The flat regions 52 may each be defined as a region that exhibits a pixel value greater than or equal to a reference value in a case where the deposition mask 20 is observed with a laser microscope from the second surface 51b side. The reference value is ½ of the maximum pixel value that may be assumed by each pixel of an image taken by the laser microscope. The laser microscope used and the observation conditions are as follows:
Laser microscope: KEYENCE CORPORATION's VK-X250
Laser light: blue (wavelength of 408 nm)
Objective lens: x50
Optical zoom: x1.0
Mode of measurement: surface profile
Quality of measurement: high-speed
Used Real Peak Detection (RPD)

As shown in FIG. 5A, each of the flat regions 52 may include a first flat region 53 and a second flat region 54. The first flat region 53 and the second flat region 54 are located between two through holes 25 adjacent to each other in the first direction D1. The first flat region 53 and the second flat region 54 are opposite to each other across a first center line L1 in the third direction D3. The first center line L1 is a straight line passing through the center points C1 of two through holes 25 adjacent to each other in the first direction D1. The first flat region 53 is located at a first side of the first center line L1. The second flat region 54 is located at a second side of the first center line L1. In the example shown in FIG. 5A, the first side is an upper side, and the second side is a lower side.

The first flat region 53 and the second flat region 54 are located between a first through hole 25 and a second through hole 25 that are adjacent to each other in the third direction D3. The first flat region 53 is located between the first through hole 25 and the first center line L1. The second flat region 54 is located between the second through hole 25 and the first center line L1.

In FIG. 5A, reference sign U1 denotes the distance between a through region 42 and a flat region 52 in the first direction D1. The distance U1 is defined at the position of the first center line L1. Reference sign U3 denotes the distance between a through region 42 and a flat region 52 in the third direction D3. The distance U3 is defined at the position of a third center line L3.

The distance U3 may be equal to the distance U1. The distance U3 may be greater than the distance U1. U3/U1, which is the ratio of the distance U3 to the distance U1, may for example be higher than or equal to 1.01, higher than or equal to 1.03, higher than or equal to 1.05, or higher than or equal to 1.10. The distance U3 may be less than the distance U1. U3//U1 may for example be lower than or equal to 0.99, lower than or equal to 0.97, lower than or equal to 0.95, or lower than or equal to 0.90.

As shown in FIG. 5A, the first flat region 53 and the second flat region 54 may be contiguous to each other in the third direction D3. That is, the first flat region 53 and the second flat region 54 may be connected to each other at the first center line L1. As will be mentioned later, the first flat region 53 and the second flat region 54 may be noncontiguous to each other. That is, a non-flat region may be present between the first flat region 53 and the second flat region 54.

As shown in FIG. 5A, no flat region 52 may be present between two through holes 25 adjacent to each other in the second direction D2. For example, two through holes 25 adjacent to each other in the second direction D2 may be connected to each other. In this case, a flat region 52 located between two through holes 25 adjacent to each other in the second direction D2 is independent from other flat regions 52 adjacent thereto in the second directions D2 and the fourth direction D4. Reference sign U2 denotes the distance between two through holes 25 adjacent to each other in the second direction D2.

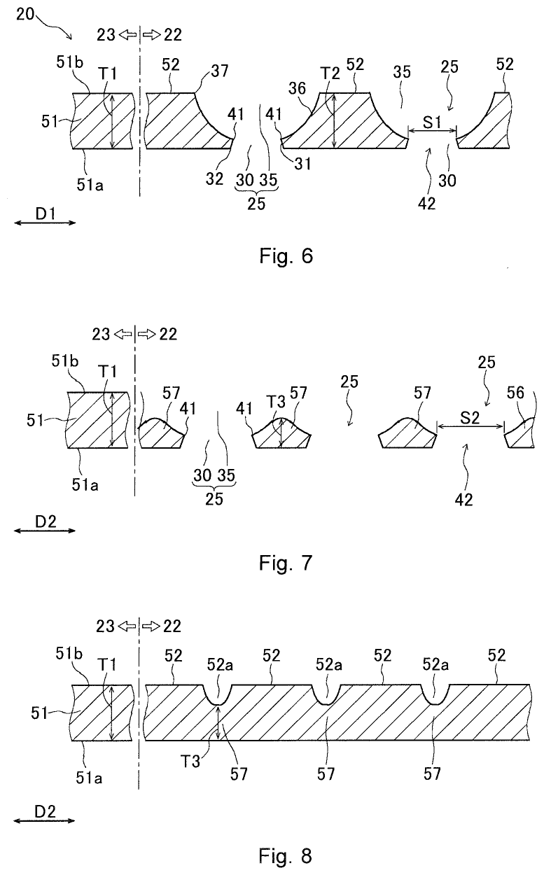

Next, cross-sectional structures of the through holes 25 and the flat regions 52 are described with reference to FIGS. 6 and 7. FIG. 6 is a cross-sectional view of the deposition mask 20 of FIG. 5A as taken along line A-A extending in the first direction D1 and passing through through holes 25. FIG. 7 is a cross-sectional view of the deposition mask 20 of FIG. 5A as taken along line B-B extending in the second direction D2 and passing through through holes 25.

As shown in FIGS. 6 and 7, each of the through holes 25 may include a first concave portion 30 and a second concave portion 35. The first concave portion 30 includes a first wall surface 31 located at the first surface 51a. The second concave portion 35 includes a second wall surface 36 located at the second surface 51b. The concave portion 35 is connected to the first concave portion 30 at a connecting portion 41. The first wall surface 31 is a surface that spreads from a first end 32 of the through hole 25 to the second surface 51b. The first end 32 is an end of the through hole 25 on the first surface 51a. The second wall surface 36 is a surface that is connected to the first wall surface 31 via the connecting portion 41 and that spreads from the connecting portion 41 to the second surface 51b and reaches a second end 37. The second end 37 is an end of the through hole 25 on the second surface 51b. As shown in FIGS. 6 and 7, the second concave portion 35 may be larger in dimension that the first concave portion 30 in a direction parallel with the plane of the deposition mask 20. For example, the contours of the second concave portion 35 may surround the contours of the first concave portion 30 in planar view.

As will be mentioned later, the first concave portion 30 may be formed by etching the metal plate 51 of the deposition mask 20 from the first surface 51a side. The second concave portion 35 may be formed by etching the metal plate 51 from the second surface 51b side. The connecting portion 41 is a portion at which the first concave portion 30 and the second concave portion 35 are connected to each other. At the connecting portion 41, a wall surface of the through hole 25 may change the direction in which the wall surface spreads. For example, the direction in which the wall surface spreads may change in a discontinuous manner.

As shown in FIGS. 6 and 7, the second wall surface 36 may include a portion that becomes gradually closer to the center point of the through hole 25 in planar view as the portion extends from the second surface 51b toward the first surface 51a. Similarly, the first wall surface 31 may include a portion that becomes gradually closer to the center point of the through hole 25 in planar view as the portion extends from the first surface 51a toward the second surface 51b. In this case, the opening area of the through hole 25 may reach its minimum at the connecting portion 41. In other words, the connecting portion 41 may demarcate the aforementioned contours of the through region 42.

In FIGS. 5A and 6, reference sign S1 denotes the maximum value of a dimension of a through region 42 in the first direction D1. In FIGS. 5A and 7, reference sign S2 denotes the maximum value of a dimension of a through region 42 in the second direction D2. The dimension S2 may be larger than the dimension S1.

S2/S1, which is the ratio of the dimension S2 to the dimension S1, may for example be higher than or equal to 1.01, higher than or equal to 1.05, or higher than or equal to 1.10. S2/S1 may for example be lower than or equal to 1.20, lower than or equal to 1.30, or lower than or equal to 1.50. S2/S1 may fall within a range defined by a first group consisting of 1.01, 1.05, and 1.10 and/or a second group consisting of 1.20, 1.30, and 1.50. S2/S1 may fall within a range defined by a combination of any one of the values included in the aforementioned first group and any one of the values included in the aforementioned second group. S2/S1 may fall within a range defined by a combination of any two of the values included in the aforementioned first group. S2/S1 may fall within a range defined by a combination of any two of the values included in the aforementioned second group. S2/S1 may for example be higher than or equal to 1.01 and lower than or equal to 1.50, higher than or equal to 1.01 and lower than or equal to 1.30, higher than or equal to 1.01 and lower than or equal to 1.20, higher than or equal to 1.01 and lower than or equal to 1.10, higher than or equal to 1.01 and lower than or equal to 1.05, higher than or equal to 1.05 and lower than or equal to 1.50, higher than or equal to 1.05 and lower than or equal to 1.30, higher than or equal to 1.05 and lower than or equal to 1.20, higher than or equal to 1.05 and lower than or equal to 1.10, higher than or equal to 1.10 and lower than or equal to 1.50, higher than or equal to 1.10 and lower than or equal to 1.30, higher than or equal to 1.10 and lower than or equal to 1.20, higher than or equal to 1.20 and lower than or equal to 1.50, higher than or equal to 1.20 and lower than or equal to 1.30, or higher than or equal to 1.30 and lower than or equal to 1.50.

In FIG. 5A, reference sign S3 denotes the maximum value of a dimension of a through region 42 in the third direction D3. The dimension S3 may be larger than the dimension S1. S3/S1, which is the ratio of the dimension S3 to the dimension S1, may for example be higher than or equal to 1.01, higher than or equal to 1.05, or higher than or equal to 1.10. S3/S1, which is the ratio of the dimension S3 to the dimension S1, may for example be lower than or equal to 1.20, lower than or equal to 1.30, or lower than or equal to 1.50. S3/S1 may fall within a range defined by a first group consisting of 1.01, 1.05, and 1.10 and/or a second group consisting of 1.20, 1.30, and 1.50. S3/S1 may fall within a range defined by a combination of any one of the values included in the aforementioned first group and any one of the values included in the aforementioned second group. S3/S1 may fall within a range defined by a combination of any two of the values included in the aforementioned first group. S3/S1 may fall within a range defined by a combination of any two of the values included in the aforementioned second group. S3/S1 may for example be higher than or equal to 1.01 and lower than or equal to 1.50, higher than or equal to 1.01 and lower than or equal to 1.30, higher than or equal to 1.01 and lower than or equal to 1.20, higher than or equal to 1.01 and lower than or equal to 1.10, higher than or equal to 1.01 and lower than or equal to 1.05, higher than or equal to 1.05 and lower than or equal to 1.50, higher than or equal to 1.05 and lower than or equal to 1.30, higher than or equal to 1.05 and lower than or equal to 1.20, higher than or equal to 1.05 and lower than or equal to 1.10, higher than or equal to 1.10 and lower than or equal to 1.50, higher than or equal to 1.10 and lower than or equal to 1.30, higher than or equal to 1.10 and lower than or equal to 1.20, higher than or equal to 1.20 and lower than or equal to 1.50, higher than or equal to 1.20 and lower than or equal to 1.30, or higher than or equal to 1.30 and lower than or equal to 1.50.

Although not illustrated, the dimension S3 may be equal to the dimension S1, or may be smaller than the dimension S1.

Next, the flat regions 52 are described. As shown in FIG. 6, the aforementioned flat regions 52 are located on the second surface 51b of the metal plate 51. The thickness T2 of each of the flat regions 52 may be equal to the thickness T1 of the metal plate 51. For example, T2/T1, which is the ratio of the thickness T1 to the thickness T2, may be higher than or equal to 0.95 and lower than or equal to 1.05. The thickness T1 of the metal plate 51 is the thickness of a region, such as the surrounding region 23, of the deposition mask 20 in which a first concave portion 30 and a second concave portion 35 are not formed.

The thickness T1 of the metal plate 51 may for example be greater than or equal to 8 μm, greater than or equal to 10 μm, greater than or equal to 13 μm, or greater than or equal to 15 μm. The thickness T1 of the metal plate 51 may for example be less than or equal to 20 μm, less than or equal to 25 μm, less than or equal to 30 μm, or less than or equal to 50 μm. The thickness T1 of the metal plate 51 may fall within a range defined by a first group consisting of 8 μm, 10 μm, 13 μm, and 15 μm and/or a second group consisting of 20 μm, 25 μm, 30 μm, and 50 μm. The thickness T1 of the metal plate 51 may fall within a range defined by a combination of any one of the values included in the aforementioned first group and any one of the values included in the aforementioned second group. The thickness T1 of the metal plate 51 may fall within a range defined by a combination of any two of the values included in the aforementioned first group. The thickness T1 of the metal plate 51 may fall within a range defined by a combination of any two of the values included in the aforementioned second group. The thickness T1 of the metal plate 51 may for example be greater than or equal to 8 μm and less than or equal to 50 μm, greater than or equal to 8 μm and less than or equal to 30 μm, greater than or equal to 8 μm and less than or equal to 25 μm, greater than or equal to 8 μm and less than or equal to 20 μm, greater than or equal to 8 μm and less than or equal to 15 μm, greater than or equal to 8 μm and less than or equal to 13 μm, greater than or equal to 8 μm and less than or equal to 10 μm, greater than or equal to 10 μm and less than or equal to 50 μm, greater than or equal to 10 μm and less than or equal to 30 μm, greater than or equal to 10 μm and less than or equal to 25 μm, greater than or equal to 10 μm and less than or equal to 20 μm, greater than or equal to 10 μm and less than or equal to 15 μm, greater than or equal to 10 μm and less than or equal to 13 μm, greater than or equal to 13 μm and less than or equal to 50 μm, greater than or equal to 13 μm and less than or equal to 30 μm, greater than or equal to 13 μm and less than or equal to 25 μm, greater than or equal to 13 μm and less than or equal to 20 μm, greater than or equal to 13 μm and less than or equal to 15 μm, greater than or equal to 15 μm and less than or equal to 50 μm, greater than or equal to 15 μm and less than or equal to 30 μm, greater than or equal to 15 μm and less than or equal to 25 μm, greater than or equal to 15 μm and less than or equal to 20 μm, greater than or equal to 20 μm and less than or equal to 50 μm, greater than or equal to 20 μm and less than or equal to 30 μm, greater than or equal to 20 μm and less than or equal to 25 μm, greater than or equal to 25 μm and less than or equal to 50 μm, greater than or equal to 25 μm and less than or equal to 30 μm, or greater than or equal to 30 μm and less than or equal to 50 μm.

Making the thickness T1 of the metal plate 51 less than or equal to 50 μm makes it possible to restrain the deposited material 98 from adhering to the first or second wall surfaces 31 or 36 of the through holes 25 before passing through the through holes 25. This makes it possible to increase efficiency in the use of the deposited material 98. Making the thickness T1 of the metal plate 51 greater than or equal to 8 μm makes it possible to ensure the strength of the deposition mask 20 to restrain the deposition mask 20 from becoming damaged or deforming.

As shown in FIG. 7, portions of the second surface 51b each located between two through holes 25 adjacent to each other in the second direction D2 are denoted by reference sign 57, and are referred to as “coupling portions”. In the present embodiment, the coupling portions 57 are non-flat regions. For example, the maximum value T3 of the thickness of each of the coupling portions 57 is smaller than the thickness T1 of the metal plate 51. As shown in FIG. 7, a surface of each of the coupling portions 57 at the second surface 51b may be curved in a concave shape toward the second surface 51b in cross-section.

The ratio of the maximum value T3 of the thickness of each of the coupling portions 57 to the thickness T1 of the metal plate 51 may for example be higher than or equal to 0.10, higher than or equal to 0.30, higher than or equal to 0.50, or higher than or equal to 0.60. T3/T1 may for example be lower than or equal to 0.70, lower than or equal to 0.80, lower than or equal to 0.90, or lower than or equal to 0.97. T3/T1 may fall within a range defined by a first group consisting of 0.10, 0.30, 0.50, and 0.60 and/or a second group consisting of 0.70, 0.80, 0.90, and 0.97. T3/T1 may fall within a range defined by a combination of any one of the values included in the aforementioned first group and any one of the values included in the aforementioned second group. T3/T1 may fall within a range defined by a combination of any two of the values included in the aforementioned first group. T3/T1 may fall within a range defined by a combination of any two of the values included in the aforementioned second group. T3/T1 may for example be higher than or equal to 0.10 and lower than or equal to 0.97, higher than or equal to 0.10 and lower than or equal to 0.90, higher than or equal to 0.10 and lower than or equal to 0.80, higher than or equal to 0.10 and lower than or equal to 0.70, higher than or equal to 0.10 and lower than or equal to 0.60, higher than or equal to 0.10 and lower than or equal to 0.50, higher than or equal to 0.10 and lower than or equal to 0.30, higher than or equal to 0.30 and lower than or equal to 0.97, higher than or equal to 0.30 and lower than or equal to 0.90, higher than or equal to 0.30 and lower than or equal to 0.80, higher than or equal to 0.30 and lower than or equal to 0.70, higher than or equal to 0.30 and lower than or equal to 0.60, higher than or equal to 0.30 and lower than or equal to 0.50, higher than or equal to 0.50 and lower than or equal to 0.97, higher than or equal to 0.50 and lower than or equal to 0.90, higher than or equal to 0.50 and lower than or equal to 0.80, higher than or equal to 0.50 and lower than or equal to 0.70, higher than or equal to 0.50 and lower than or equal to 0.60, higher than or equal to 0.60 and lower than or equal to 0.97, higher than or equal to 0.60 and lower than or equal to 0.90, higher than or equal to 0.60 and lower than or equal to 0.80, higher than or equal to 0.60 and lower than or equal to 0.70, higher than or equal to 0.70 and lower than or equal to 0.97, higher than or equal to 0.70 and lower than or equal to 0.90, higher than or equal to 0.70 and lower than or equal to 0.80, higher than or equal to 0.80 and lower than or equal to 0.97, higher than or equal to 0.80 and lower than or equal to 0.90, or higher than or equal to 0.90 and lower than or equal to 0.97.

The aforementioned thicknesses T1, T2, and T3 are calculated by observing a cross-section of a deposition mask 20 with a scanning electron microscope. For example, the thicknesses T1 and T2 are calculated by measuring the thicknesses T1 and T2 of five parts of a sample deposition mask 20 including an effective region 22 and a surrounding region 23 and including a cross-section taken along the first direction D1 and by calculating the averages of the thicknesses thus measured. The thickness T3 is calculated by measuring the thicknesses T3 of five parts of a sample deposition mask 20 including flat regions 52 and a cross-section taken along the second direction D2 and by calculating the average of the thicknesses thus measured. As the scanning electron microscope, a scanning electron microscope ZEISS ULTRA 55 can be used.

FIG. 8 is a cross-sectional view of the deposition mask 20 of FIG. 5A as taken along line C-C extending in the second direction D2 and passing through flat regions 52. In the cross-sectional view of FIG. 8, each of the coupling portions 57 overlaps a depression 52a situated between two flat regions 52 adjacent to each other in the second direction D2.

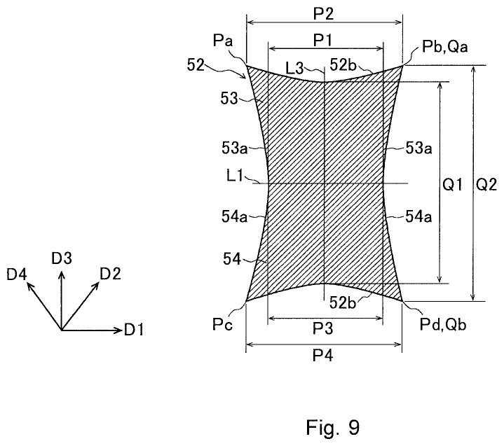

Next, the shape of each of the flat regions 52 in planar view is further described with reference to FIGS. 5A and 9. FIG. 9 is an enlarged plan view of the first and second flat regions 53 and 54 of FIG. 5A.

As shown in FIG. 5A, the first flat region 53 may include a portion in which the dimension E1 increases upward away from the first center line L1. The dimension E1 is a dimension of the first flat region 53 in the first direction D1. The second flat region 54 may include a portion in which the dimension E2 increases downward away from the first center line L1. The dimension E2 is a dimension of the second flat region 54 in the first direction D1. For example, as shown in FIG. 5A, a portion of the contours of the flat region 52 that faces a through hole 25 in the first direction D1 may be curved so as to be depressed toward the center of the flat region 52.

As shown in FIG. 5A, the flat region 52 may include portion in which the dimension G1 increases in the first direction D1 away from the third center line L3. The dimension G1 is a dimension of the flat region 52 in the third direction D3. For example, as shown in FIG. 5A, a portion of the counters of the flat region 52 that faces a through hole 25 in the third direction D3 may be curved so as to be depressed toward the center of the flat region 52. The third center line L3 is a straight line passing through a midpoint C2 between two through holes 25 adjacent to each other in the first direction D1 and extending in the third direction D3.

In FIG. 9, reference sign P1 denotes a dimension in the first direction D1 of a portion of the first flat region 53 that overlaps the first center line L1. Reference sign P2 denotes the distance in the first direction D1 between ends Pa and Pb of two first contours 53a of the first flat region 53. The ends Pa and Pb are located away from the first center liner L1. Each of the first contours 53a is a portion of the contours of the first flat region 53 that faces a through hole 25 in the first direction D1. As shown in FIG. 9, the dimension P1 may be smaller than the distance P2.

The ratio of the dimension P1 to the distance P2 may for example be higher than or equal to 0.01, higher than or equal to 0.10, higher than or equal to 0.30, or higher than or equal to 0.45. P1/P2 may for example be lower than or equal to 0.60, lower than or equal to 0.70, lower than or equal to 0.80, or lower than or equal to 0.90. P1/P2 may fall within a range defined by a first group consisting of 0.01, 0.10, 0.30, and 0.45 and/or a second group consisting of 0.60, 0.70, 0.80, and 0.90. P1/P2 may fall within a range defined by a combination of any one of the values included in the aforementioned first group and any one of the values included in the aforementioned second group. P1/P2 may fall within a range defined by a combination of any two of the values included in the aforementioned first group. P1/P2 may fall within a range defined by a combination of any two of the values included in the aforementioned second group. P1/P2 may for example be higher than or equal to 0.01 and lower than or equal to 0.90, higher than or equal to 0.01 and lower than or equal to 0.80, higher than or equal to 0.01 and lower than or equal to 0.70, higher than or equal to 0.01 and lower than or equal to 0.60, higher than or equal to 0.01 and lower than or equal to 0.45, higher than or equal to 0.01 and lower than or equal to 0.30, higher than or equal to 0.01 and lower than or equal to 0.10, higher than or equal to 0.10 and lower than or equal to 0.90, higher than or equal to 0.10 and lower than or equal to 0.80, higher than or equal to 0.10 and lower than or equal to 0.70, higher than or equal to 0.10 and lower than or equal to 0.60, higher than or equal to 0.10 and lower than or equal to 0.45, higher than or equal to 0.10 and lower than or equal to 0.30, higher than or equal to 0.30 and lower than or equal to 0.90, higher than or equal to 0.30 and lower than or equal to 0.80, higher than or equal to 0.30 and lower than or equal to 0.70, higher than or equal to 0.30 and lower than or equal to 0.60, higher than or equal to 0.30 and lower than or equal to 0.45, higher than or equal to 0.45 and lower than or equal to 0.90, higher than or equal to 0.45 and lower than or equal to 0.80, higher than or equal to 0.45 and lower than or equal to 0.70, higher than or equal to 0.45 and lower than or equal to 0.60, higher than or equal to 0.60 and lower than or equal to 0.90, higher than or equal to 0.60 and lower than or equal to 0.80, higher than or equal to 0.60 and lower than or equal to 0.70, higher than or equal to 0.70 and lower than or equal to 0.90, higher than or equal to 0.70 and lower than or equal to 0.80, or higher than or equal to 0.80 and lower than or equal to 0.90.

In FIG. 9, reference sign P3 denotes a dimension in the first direction D1 of a portion of the second flat region 54 that overlaps the first center line L1. Reference sign P4 denotes the distance in the first direction D1 between ends Pc and Pd of two first contours 54a of the second flat region 54. The ends Pc and Pd are located away from the first center liner L1. Each of the second contours 54a is a portion of the contours of the second flat region 54 that faces a through hole 25 in the first direction D1. In a case where the first flat region 53 and the second flat region 54 are contiguous to each other, the dimension P3 of the second flat region 54 is equal to the aforementioned dimension P1 of the first flat region 53.

The range of numerical values of the ratio of the dimension P3 to the distance P4 in the second flat region 54 is not described, as it is similar to the range of numerical values of the ratio of the dimension P1 to the distance P2 in the first flat region 53.

In FIG. 9, reference sign Q1 denotes a dimension in the third direction D3 of a portion of the flat region 52 that overlaps the third center line L3. Reference sign Q2 denotes the distance in the third direction D3 between ends Qa and Qb of two second contours 52b of the flat region 52 including the first flat region 53 and the second flat region 54. The ends Qa and Qb are located away from the first center line L1. Each of the second contours 52b is a portion of the contours of the flat region 52 that faces a through hole 25 in the third direction D3. As shown in FIG. 9, the dimension Q1 may be smaller than the distance Q2. Alternatively, as will be mentioned later, the dimension Q1 may be equal to the distance Q2.

The ratio of the dimension Q1 to the distance Q2 may for example be higher than or equal to 0.30, higher than or equal to 0.40, higher than or equal to 0.50, or higher than or equal to 0.60. Q1/Q2 may for example be lower than or equal to 0.70, lower than or equal to 0.80, lower than or equal to 0.90, or lower than or equal to 1.00. Q1/Q2 may fall within a range defined by a first group consisting of 0.30, 0.30, 0.50, and 0.60 and/or a second group consisting of 0.70, 0.80, 0.90, and 1.00. Q1/Q2 may fall within a range defined by a combination of any one of the values included in the aforementioned first group and any one of the values included in the aforementioned second group. Q1/Q2 may fall within a range defined by a combination of any two of the values included in the aforementioned first group. Q1/Q2 may fall within a range defined by a combination of any two of the values included in the aforementioned second group. Q1/Q2 may for example be higher than or equal to 0.30 and lower than or equal to 1.00, higher than or equal to 0.30 and lower than or equal to 0.90, higher than or equal to 0.30 and lower than or equal to 0.80, higher than or equal to 0.30 and lower than or equal to 0.70, higher than or equal to 0.30 and lower than or equal to 0.60, higher than or equal to 0.30 and lower than or equal to 0.50, higher than or equal to 0.30 and lower than or equal to 0.40, higher than or equal to 0.40 and lower than or equal to 1.00, higher than or equal to 0.40 and lower than or equal to 0.90, higher than or equal to 0.40 and lower than or equal to 0.80, higher than or equal to 0.40 and lower than or equal to 0.70, higher than or equal to 0.40 and lower than or equal to 0.60, higher than or equal to 0.40 and lower than or equal to 0.50, higher than or equal to 0.50 and lower than or equal to 1.00, higher than or equal to 0.50 and lower than or equal to 0.90, higher than or equal to 0.50 and lower than or equal to 0.80, higher than or equal to 0.50 and lower than or equal to 0.70, higher than or equal to 0.50 and lower than or equal to 0.60, higher than or equal to 0.60 and lower than or equal to 1.00, higher than or equal to 0.60 and lower than or equal to 0.90, higher than or equal to 0.60 and lower than or equal to 0.80, higher than or equal to 0.60 and lower than or equal to 0.70, higher than or equal to 0.70 and lower than or equal to 1.00, higher than or equal to 0.70 and lower than or equal to 0.90, higher than or equal to 0.70 and lower than or equal to 0.80, higher than or equal to 0.80 and lower than or equal to 1.00, higher than or equal to 0.80 and lower than or equal to 0.90, or higher than or equal to 0.90 and lower than or equal to 1.00.

The dimension Q1 may be larger than the dimension P1. That is, the flat region 52 may have a shape extending in the third direction D3. Q1/P1, which is the ratio of the dimension Q1 to the dimension P1, may for example be higher than or equal to 1.05, higher than or equal to 1.2, higher than or equal to 1.5, or higher than or equal to 2.0. Q1/P1 may for example be lower than or equal to 2.5, lower than or equal to 5.0, lower than or equal to 10, or lower than or equal to 50. Q1/P1 may fall within a range defined by a first group consisting of 1.05, 1.2, 1.5, and 2.0 and/or a second group consisting of 2.5, 5.0, 10, and 50. Q1/P1 may fall within a range defined by a combination of any one of the values included in the aforementioned first group and any one of the values included in the aforementioned second group. Q1/P1 may fall within a range defined by a combination of any two of the values included in the aforementioned first group. Q1/P1 may fall within a range defined by a combination of any two of the values included in the aforementioned second group. Q1/P1 may for example be higher than or equal to 1.05 and lower than or equal to 50, higher than or equal to 1.05 and lower than or equal to 10, higher than or equal to 1.05 and lower than or equal to 5.0, higher than or equal to 1.05 and lower than or equal to 2.5, higher than or equal to 1.05 and lower than or equal to 2.0, higher than or equal to 1.05 and lower than or equal to 1.5, higher than or equal to 1.05 and lower than or equal to 1.2, higher than or equal to 1.2 and lower than or equal to 50, higher than or equal to 1.2 and lower than or equal to 10, higher than or equal to 1.2 and lower than or equal to 5.0, higher than or equal to 1.2 and lower than or equal to 2.5, higher than or equal to 1.2 and lower than or equal to 2.0, higher than or equal to 1.2 and lower than or equal to 1.5, higher than or equal to 1.5 and lower than or equal to 50, higher than or equal to 1.5 and lower than or equal to 10, higher than or equal to 1.5 and lower than or equal to 5.0, higher than or equal to 1.5 and lower than or equal to 2.5, higher than or equal to 1.5 and lower than or equal to 2.0, higher than or equal to 2.0 and lower than or equal to 50, higher than or equal to 2.0 and lower than or equal to 10, higher than or equal to 2.0 and lower than or equal to 5.0, higher than or equal to 2.0 and lower than or equal to 2.5, higher than or equal to 2.5 and lower than or equal to 50, higher than or equal to 2.5 and lower than or equal to 10, higher than or equal to 2.5 and lower than or equal to 5.0, higher than or equal to 5.0 and lower than or equal to 50, higher than or equal to 5.0 and lower than or equal to 10, or higher than or equal to 10 and lower than or equal to 50.

The dimension Q2 may be larger than the dimension P2. As the range of numerical values of Q2/P2, which is the ratio of the dimension Q2 to the dimension P2, the aforementioned range of numerical values of Q1/P1 can be employed. As in the case of the dimension Q1 and the dimension P1, it is meant by the dimension Q2 being larger than the dimension P2 that the flat region 52 has a shape extending in the third direction D3.

The third direction D3 may coincide with the mask first direction N1. An angle that the third direction D3 and the mask first direction N1 form with each other may be less than or equal to 5.0 degrees, less than or equal to 3.0 degrees, less than or equal to 1.0 degree, less than or equal to 0.5 degree, or less than or equal to 0.1 degree. The mask first direction N1 may be set based on a direction in which side edges 17c of the deposition mask 20 extend. In a case where the deposition mask 20 includes two alignment marks arranged along the side edges 17c, the mask first direction N1 may be set based on a direction in which a straight line passing through the centers of the two alignment marks extends.

The coincidence of the third direction D3 with the mask first direction N1 means that a length direction of the flat region 52 coincides with the length direction of the deposition mask 20. When fixed to the frame 15, the deposition mask 20 may be under lengthwise tension. In a case where the length direction of the flat region 52 coincides with the length direction of the deposition mask 20, the shape of the flat region 52 in planar view can be restrained from changing due to tension. This makes it possible, for example, to restrain the deposition mask 20 from becoming wrinkled due to tension.

As the ratio of the areas of the flat regions 52 to the area of the effective region 22 becomes higher, the strength of the deposition mask 20 becomes higher. As the strength of the deposition mask 20 becomes higher, the workability of a step involving the use of the deposition mask 20 becomes higher. For example, the deposition mask 20 can be restrained from deforming or becoming damaged when the deposition mask 20 is carried. Meanwhile, as the ratio of the areas of the flat regions 52 to the area of the effective region 22 becomes higher, the likelihood of a shadow becomes higher. The dimensions, such as P1, P2, Q1, and Q2, of each of the flat regions 52 are set in view of strength and a shadow. Relationships between the dimensions of the flat region 52 and the other dimensions are described below.

As the distances U1, U2, and U3 shown in FIG. 5A become greater, the strength of the deposition mask 20 becomes lower, although a shadow is suppressed. The dimensions of the flat region 52 may be set in view of these distances.

U2/Q1, which is the ratio of the distance U2 to the dimension Q1, may for example be higher than or equal to 0.05, higher than or equal to 0.15, higher than or equal to 0.3, or higher than or equal to 0.5. U2/Q1 may for example be lower than or equal to 0.8, lower than or equal to 1.0, lower than or equal to 1.2, or lower than or equal to 1.5. U2/Q1 may fall within a range defined by a first group consisting of 0.05, 0.15, 0.3, and 0.5 and/or a second group consisting of 0.8, 1.0, 1.2, and 1.5. U2/Q1 may fall within a range defined by a combination of any one of the values included in the aforementioned first group and any one of the values included in the aforementioned second group. U2/Q1 may fall within a range defined by a combination of any two of the values included in the aforementioned first group. U2/Q1 may fall within a range defined by a combination of any two of the values included in the aforementioned second group. U2/Q1 may for example be higher than or equal to 0.05 and lower than or equal to 1.5, higher than or equal to 0.05 and lower than or equal to 1.2, higher than or equal to 0.05 and lower than or equal to 1.0, higher than or equal to 0.05 and lower than or equal to 0.8, higher than or equal to 0.05 and lower than or equal to 0.5, higher than or equal to 0.05 and lower than or equal to 0.3, higher than or equal to 0.05 and lower than or equal to 0.15, higher than or equal to 0.15 and lower than or equal to 1.5, higher than or equal to 0.15 and lower than or equal to 1.2, higher than or equal to 0.15 and lower than or equal to 1.0, higher than or equal to 0.15 and lower than or equal to 0.8, higher than or equal to 0.15 and lower than or equal to 0.5, higher than or equal to 0.15 and lower than or equal to 0.3, higher than or equal to 0.3 and lower than or equal to 1.5, higher than or equal to 0.3 and lower than or equal to 1.2, higher than or equal to 0.3 and lower than or equal to 1.0, higher than or equal to 0.3 and lower than or equal to 0.8, higher than or equal to 0.3 and lower than or equal to 0.5, higher than or equal to 0.5 and lower than or equal to 1.5, higher than or equal to 0.5 and lower than or equal to 1.2, higher than or equal to 0.5 and lower than or equal to 1.0, higher than or equal to 0.5 and lower than or equal to 0.8, higher than or equal to 0.8 and lower than or equal to 1.5, higher than or equal to 0.8 and lower than or equal to 1.2, higher than or equal to 0.8 and lower than or equal to 1.0, higher than or equal to 1.0 and lower than or equal to 1.5, higher than or equal to 1.0 and lower than or equal to 1.2, or higher than or equal to 1.2 and lower than or equal to 1.5.

As the range of numerical values of U2/Q2, which is the ratio of the distance U2 to the dimension Q2, the aforementioned range of numerical values of U2/Q1 can be employed.

U3/Q1, which is the ratio of the distance U3 to the dimension Q1, may for example be higher than or equal to 0.02, higher than or equal to 0.05, higher than or equal to 0.10, or higher than or equal to 0.20. U3/Q1 may for example be lower than or equal to 0.30, lower than or equal to 0.50, lower than or equal to 0.70, or lower than or equal to 1.00. U3/Q1 may fall within a range defined by a first group consisting of 0.02, 0.05, 0.10, and 0.20 and/or a second group consisting of 0.30, 0.50, 0.70, and 1.00. U3/Q1 may fall within a range defined by a combination of any one of the values included in the aforementioned first group and any one of the values included in the aforementioned second group. U3/Q1 may fall within a range defined by a combination of any two of the values included in the aforementioned first group. U3/Q1 may fall within a range defined by a combination of any two of the values included in the aforementioned second group. U3/Q1 may for example be higher than or equal to 0.02 and lower than or equal to 1.00, higher than or equal to 0.02 and lower than or equal to 0.70, higher than or equal to 0.02 and lower than or equal to 0.50, higher than or equal to 0.02 and lower than or equal to 0.30, higher than or equal to 0.02 and lower than or equal to 0.20, higher than or equal to 0.02 and lower than or equal to 0.10, higher than or equal to 0.02 and lower than or equal to 0.05, higher than or equal to 0.05 and lower than or equal to 1.00, higher than or equal to 0.05 and lower than or equal to 0.70, higher than or equal to 0.05 and lower than or equal to 0.50, higher than or equal to 0.05 and lower than or equal to 0.30, higher than or equal to 0.05 and lower than or equal to 0.20, higher than or equal to 0.05 and lower than or equal to 0.10, higher than or equal to 0.10 and lower than or equal to 1.00, higher than or equal to 0.10 and lower than or equal to 0.70, higher than or equal to 0.10 and lower than or equal to 0.50, higher than or equal to 0.10 and lower than or equal to 0.30, higher than or equal to 0.10 and lower than or equal to 0.20, higher than or equal to 0.20 and lower than or equal to 1.00, higher than or equal to 0.20 and lower than or equal to 0.70, higher than or equal to 0.20 and lower than or equal to 0.50, higher than or equal to 0.20 and lower than or equal to 0.30, higher than or equal to 0.30 and lower than or equal to 1.00, higher than or equal to 0.30 and lower than or equal to 0.70, higher than or equal to 0.30 and lower than or equal to 0.50, higher than or equal to 0.50 and lower than or equal to 1.00, higher than or equal to 0.50 and lower than or equal to 0.70, or higher than or equal to 0.70 and lower than or equal to 1.00.

As the range of numerical values of U3/Q2, which is the ratio of the distance U3 to the dimension Q2, the aforementioned range of numerical values of U3/Q1 can be employed.

As the dimensions S1, S2, and S3 of each of the through holes 25 shown in FIG. 5A become larger, the strength of the deposition mask 20 becomes lower, although the effect of a shadow becomes smaller. The dimensions of the flat region 52 may be set in view of the dimensions of the through hole 25.

S3/Q1, which is the ratio of the dimension S3 to the dimension Q1, may for example be higher than or equal to 0.5, higher than or equal to 0.6, higher than or equal to 0.7, or higher than or equal to 0.8. S3/Q1 may for example be lower than or equal to 1.0, lower than or equal to 1.2, lower than or equal to 1.5, or lower than or equal to 2.0. S3/Q1 may fall within a range defined by a first group consisting of 0.5, 0.6, 0.7, and 0.8 and/or a second group consisting of 1.0, 1.2, 1.5, and 2.0. S3/Q1 may fall within a range defined by a combination of any one of the values included in the aforementioned first group and any one of the values included in the aforementioned second group. S3/Q1 may fall within a range defined by a combination of any two of the values included in the aforementioned first group. S3/Q1 may fall within a range defined by a combination of any two of the values included in the aforementioned second group. S3/Q1 may for example be higher than or equal to 0.5 and lower than or equal to 2.0, higher than or equal to 0.5 and lower than or equal to 1.5, higher than or equal to 0.5 and lower than or equal to 1.2, higher than or equal to 0.5 and lower than or equal to 1.0, higher than or equal to 0.5 and lower than or equal to 0.8, higher than or equal to 0.5 and lower than or equal to 0.7, higher than or equal to 0.5 and lower than or equal to 0.6, higher than or equal to 0.6 and lower than or equal to 2.0, higher than or equal to 0.6 and lower than or equal to 1.5, higher than or equal to 0.6 and lower than or equal to 1.2, higher than or equal to 0.6 and lower than or equal to 1.0, higher than or equal to 0.6 and lower than or equal to 0.8, higher than or equal to 0.6 and lower than or equal to 0.7, higher than or equal to 0.7 and lower than or equal to 2.0, higher than or equal to 0.7 and lower than or equal to 1.5, higher than or equal to 0.7 and lower than or equal to 1.2, higher than or equal to 0.7 and lower than or equal to 1.0, higher than or equal to 0.7 and lower than or equal to 0.8, higher than or equal to 0.8 and lower than or equal to 2.0, higher than or equal to 0.8 and lower than or equal to 1.5, higher than or equal to 0.8 and lower than or equal to 1.2, higher than or equal to 0.8 and lower than or equal to 1.0, higher than or equal to 1.0 and lower than or equal to 2.0, higher than or equal to 1.0 and lower than or equal to 1.5, higher than or equal to 1.0 and lower than or equal to 1.2, higher than or equal to 1.2 and lower than or equal to 2.0, higher than or equal to 1.2 and lower than or equal to 1.5, or higher than or equal to 1.5 and lower than or equal to 2.0.

As the range of numerical values of S3/Q2, which is the ratio of the dimension S3 to the dimension Q2, the aforementioned range of numerical values of S3/Q1 can be employed.

The aforementioned dimensions, such as S1, S2, S3, P1, P2, P3, P4, Q1, Q2, M1, M2, M3, U1, U2, and U3, are calculated by observing the deposition mask 20 from the second surface 51b side with a laser microscope. For example, the dimensions S1, S2, S3, P1, P2, P3, P4, Q1, Q2, M1, M2, M3, U1, U2, and U3 are calculated by measuring the dimensions S1, S2, S3, P1, P2, P3, P4, Q1, Q2, M1, M2, M3, U1, U2, and U3 of five parts of a sample deposition mask 20 including an effective region 22 and by calculating the averages of the dimensions thus measured. The laser microscope used and the observation conditions are as follows:
Laser microscope: KEYENCE CORPORATION's VK-X250
Laser light: blue (wavelength of 408 nm)
Objective lens: x50
Optical zoom: x1.0
Mode of measurement: surface profile
Quality of measurement: high-speed
Used Real Peak Detection (RPD)

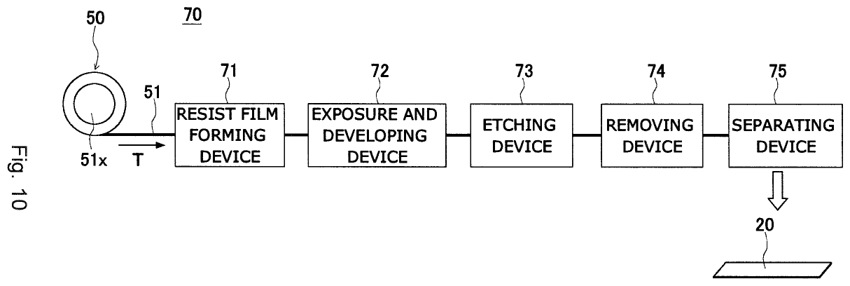

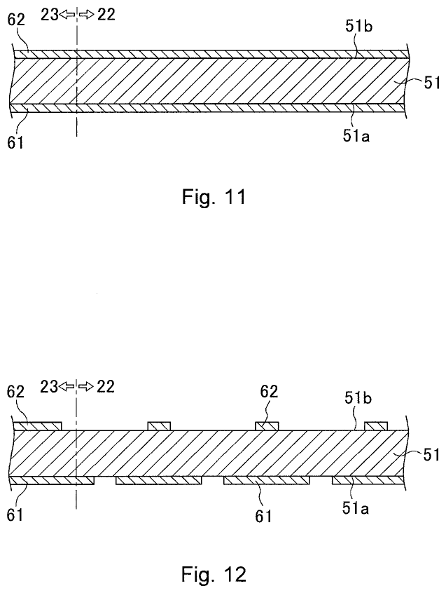

Next, a method for manufacturing a deposition mask 20 by processing a metal plate 51 is described mainly with reference to FIGS. 10 to 15. FIG. 10 is a diagram showing a manufacturing apparatus 70 for manufacturing a deposition mask 20 from a metal plate 51. First, a roll 50 including a metal plate 51 wound around a shaft member 51x is prepared. Then, the metal plate 51 of the roll 50 is unwound from the shaft member 51x, and the metal plate 51 is sequentially conveyed to a resist film forming device 71, an exposure and developing device 72, an etching device 73, a removing device 74, and a separating device 75 that are shown in FIG. 10. Although FIG. 10 illustrates an example in which the metal plate 51 moves from one device to another by being conveyed in a direction T parallel with the length of the metal plate 51, this is not intended to impose any limitation. For example, resist layers may be formed on the metal plate 51 by the resist film forming device 71, and then the metal plate 51 may be rewound around the shaft member 51x. The metal plate 51 thus rewound may be supplied to the exposure and developing device 72. The resist layers on the metal plate 51 may be subjected to exposure and developing processes by the exposure and developing device 72, and then the metal plate 51 may be rewound around the shaft member 51x. The metal plate 51 thus rewound may be supplied to the etching device 73. The metal plate 51 may be subjected to etching by the etching device 73, and then the metal plate 51 may be rewound around the shaft member 51x. The metal plate 51 thus rewound may be supplied to the removing device 74. The after-mentioned resin 58 or other constituent elements may be removed from the metal plate 51 by the removing device 74, and then the metal plate 51 may be rewound around the shaft member 51x. The metal plate 51 thus rewound may be supplied to the separating device 75.

The resist film forming device 71 forms resist layers on first and second surfaces of the metal plate 51. The exposure and developing device 72 patterns the resist layers by subjecting the resist layers to an exposure process and a developing process.

The etching device 73 etches the metal plate 51 with the patterned resist layers as masks, and form through holes 25 in the metal plate 51. In the present embodiment, the etching device 73 forms, in the metal plate 51, a large number of through holes 25 corresponding to a plurality of deposition masks 20. In other words, the etching device 73 allocates the plurality of deposition masks 20 to the metal plate 51. For example, the etching device 73 forms a large number of through holes 25 in the metal plate 51 so that effective regions 22 are arranged in a direction parallel with the width of the metal plate 51 and effective regions 22 for use in the plurality of deposition masks 20 are arranged in a direction parallel with the length of the metal plate 51. The removing device 74 removes constituent elements provided to protect, from an etchant, portions of the metal plate 51 that are not etched. Examples of the constituent elements include the resist patterns and the after-mentioned resin 58.

The separating device 75 executes a separating step of separating, from the metal plate 51, a portion of the metal plate 51 in which a plurality of through holes 25 corresponding to one deposition mask 20 has been formed. In this way, a deposition mask 20 can be obtained.

The steps of the method for manufacturing a deposition mask 20 are described in detail.

First, a roll 50 including a metal plate 51 wound around a shaft member 51x is prepared. The thickness of the metal plate 51 is for example greater than or equal to 5 μm and less than or equal to 50 μm. Employable examples of methods for fabricating a metal plate 51 having a desired thickness include rolling and plating.

A usable example of the metal plate 51 is a metal plate constituted by a nickel-containing iron alloy. The iron alloy constituting the metal plate 51 may further contain cobalt in addition to nickel. For example, the metal plate 51 can be made of a material such as an iron alloy with a total nickel and cobalt content of 30 mass % or higher and 54 mass % or lower and a cobalt content of 0 mass % or higher and 6 mass % or lower. Specific examples of nickel-containing and nickel-and-cobalt-containing iron alloys include an Invar material containing 34 mass % or higher and 38 mass % or lower of nickel, a Super-Invar material further containing cobalt in addition to 30 mass % or higher and 34 mass % or lower of nickel, and a low thermal expansion Fe—Ni plated alloy containing 38 mass % or higher and 54 mass % or lower of nickel.

Then, the metal plate 51 is unwound from an unwinding device, and the resist film forming device 71 is used to form a first surface resist layer 61 and a second surface resist layer 62 on the first and second surfaces 51a and 51b, respectively, of the metal plate 51 thus unwound. For example, the first surface resist layer 61 and the second surface resist layer 62 are formed by attaching dry films containing a photosensitive resist material such as acrylic photo-curable resin onto the first and second surfaces 51a and 51b of the metal plate 51. Alternatively, the first surface resist layer 61 and the second surface resist layer 62 may be formed by applying an application liquid containing a negative photosensitive resist material onto the first and second surfaces 51a and 51b of the metal plate 51 and by drying the application liquid.

The thickness of each of the resist layers 61 and 62 may for example be greater than or equal to 1 μm, greater than or equal to 3 μm, greater than or equal to 5 μm, or greater than or equal to 7 μm. The thickness of each of the resist layers 61 and 62 may for example be less than or equal to 10 μm, less than or equal to 15 μm, less than or equal to 20 μm, or less than or equal to 25 μm. The thickness of each of the resist layers 61 and 62 may fall within a range defined by a first group consisting of 1 μm, 3 μm, 5 μm, and 7 μm and/or a second group consisting of 10 μm, 5 μm, 20 μm, and 25 μm. The thickness of each of the resist layers 61 and 62 may fall within a range defined by a combination of any one of the values included in the aforementioned first group and any one of the values included in the aforementioned second group. The thickness of each of the resist layers 61 and 62 may fall within a range defined by a combination of any two of the values included in the aforementioned first group. The thickness of each of the resist layers 61 and 62 may fall within a range defined by a combination of any two of the values included in the aforementioned second group. The thickness of each of the resist layers 61 and 62 may for example be greater than or equal to 1 μm and less than or equal to 25 μm, greater than or equal to 1 μm and less than or equal to 20 μm, greater than or equal to 1 μm and less than or equal to 15 μm, greater than or equal to 1 μm and less than or equal to 10 μm, greater than or equal to 1 μm and less than or equal to 7 μm, greater than or equal to 1 μm and less than or equal to 5 μm, greater than or equal to 1 μm and less than or equal to 3 μm, greater than or equal to 3 μm and less than or equal to 25 μm, greater than or equal to 3 μm and less than or equal to 20 μm, greater than or equal to 3 μm and less than or equal to 15 μm, greater than or equal to 3 μm and less than or equal to 10 μm, greater than or equal to 3 μm and less than or equal to 7 μm, greater than or equal to 3 μm and less than or equal to 5 μm, greater than or equal to 5 μm and less than or equal to 25 μm, greater than or equal to 5 μm and less than or equal to 20 μm, greater than or equal to 5 μm and less than or equal to 15 μm, greater than or equal to 5 μm and less than or equal to 10 μm, greater than or equal to 5 μm and less than or equal to 7 μm, greater than or equal to 7 μm and less than or equal to 25 μm, greater than or equal to 7 μm and less than or equal to 20 μm, greater than or equal to 7 μm and less than or equal to 15 μm, greater than or equal to 7 μm and less than or equal to 10 μm, greater than or equal to 10 μm and less than or equal to 25 μm, greater than or equal to 10 μm and less than or equal to 20 μm, greater than or equal to 10 μm and less than or equal to 15 μm, greater than or equal to 15 μm and less than or equal to 25 μm, greater than or equal to 15 μm and less than or equal to 20 μm, or greater than or equal to 20 μm and less than or equal to 25 μm.

Then, the exposure and developing device 72 is used to expose and develop the resist layers 61 and 62. FIG. 12 is a cross-sectional view of the resist layers 61 and 62 patterned by exposure and development.

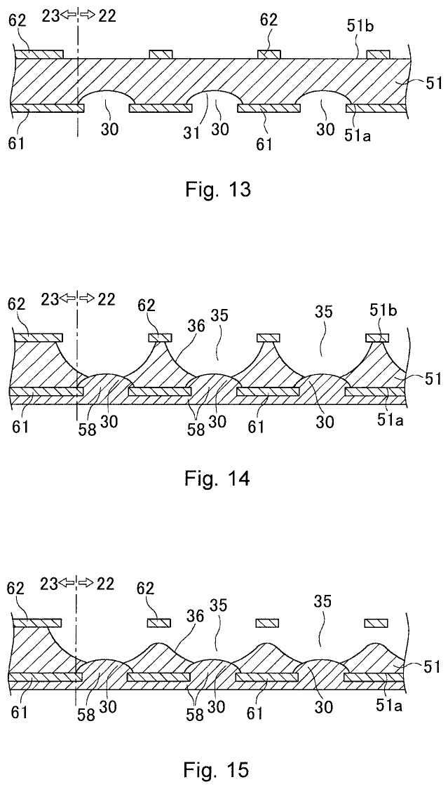

Then, the etching device 73 is used to etch the metal plate 51 with the resist layers 61 and 62 as masks. Specifically, first, a first surface etching step is executed. As shown in FIG. 13, the first surface etching step includes etching, with a first etchant, regions on the first surface 51a of the metal plate 51 not covered with the first surface resist layer 61. For example, from a nozzle placed opposite the first surface 51a of the metal plate 51 being conveyed, the first etchant is ejected toward the first surface 51a of the metal plate 51 across the first surface resist layer 61. During the first surface etching step, the second surface 51b of the metal plate 51 may be covered with a film having resistance to the first etchant.

As a result of the first surface etching step, as shown in FIG. 13, the regions on the metal plate 51 not covered with the first surface resist layer 61 are further eroded by the first etchant. This causes a large number of first concave portions 30 to be formed in the first surface 51a of the metal plate 51. A usable example of the first etchant contains a ferric chloride solution and hydrochloric acid.

Next, as shown in FIG. 14, a second surface etching step is executed. The second surface etching step includes etching, with a second etchant, regions on the second surface 51b of the metal plate 51 not covered with the second surface resist layer 62. This causes second concave portions 35 to be formed in the second surface 51b of the metal plate 51. The second surface etching step is executed until through holes 25 are formed by the first concave portions 30 and the second concave portions 35 communicating with each other. As is the case with the aforementioned first etchant, a usable example of the second etchant contains a ferric chloride solution and hydrochloric acid. In etching the second surface 51b, as shown in FIG. 14, the first concave portions 30 may be covered with resin 58 having resistance to the second etchant.

The second surface etching step may be executed so that as shown in FIG. 14, the second surface 51b of the metal plate 51 partially remains between two second concave portions 35 adjacent to each other in a particular direction. For example, the second surface etching step may be executed so that the second surface 51b of the metal plate 51 partially remains between two second concave portions 35 adjacent to each other in the first direction D1. This makes it possible to, as shown in FIG. 6, obtain flat regions 52 each located between two through holes 25 adjacent to each other in the first direction D1. The second surface etching step may be executed so that the aforementioned first and second flat regions 53 and 54 of each of the flat regions 52 are contiguous to each other.

The second surface etching step may be executed so that as shown in FIG. 15, the second surface 51b does not remain between two second concave portions 35 adjacent to each other in a particular direction. For example, the second surface etching step may be executed so that the second surface 51b does not remain between two second concave portions 35 adjacent to each other in the second direction D2. This makes it possible to, as shown in FIG. 7, obtain non-flat coupling portions 57 each located between two through holes 25 adjacent to each other in the second direction D2.

Then, the removing device 74 is used to execute a removing step of removing the resin 58 and the resist layers 61 and 62 from the metal plate 51. Then, the separating device 75 is used to separate, from the metal plate 51, a portion of the metal plate 51 in which a plurality of through holes 25 corresponding to one deposition mask 20 has been formed. In this way, a deposition mask 20 can be obtained.

In a deposition mask 20 of the present embodiment, as mentioned above, the dimension E1 of the flat region 53 and the dimension E2 of the second flat region 54 in the first direction D1 increase away from the first center line L1. Such a structure is achieved by appropriately adjusting the shapes of the resist layers 61 and 62 in planar view and etching conditions. Examples of the etching conditions include temperature, time, and the composition of the etchants.

Next, a method for manufacturing an organic EL display device 100 using a deposition mask 20 according to the present embodiment is described. The method for manufacturing an organic EL display device 100 includes a deposition step of depositing a deposited material 98 on a substrate 110 using the deposition mask 20. In the deposition step, first, the deposition mask device 10 is placed so that the deposition mask 20 faces the substrate 110. In so doing, the magnet 93 may be used to bring the deposition mask 20 into close contact with the substrate 110. Further, the interior of the deposition apparatus 90 is brought into a vacuum atmosphere. In this state, the deposited material 98 is evaporated to fly to the substrate 110 via the deposition mask 20, whereby deposited layers can be formed by causing the deposited material 98 to adhere to the substrate 110 in a pattern corresponding to the through holes 25 of the deposition mask 20.

In the deposition mask 20 of the present embodiment, the flat region 53 and the second region 54 include portions in which the dimensions E1 and E2 increase away from the first center line L1, respectively. For this reason, a portion of the deposited material 98 having a velocity component in the first direction D1 and migrating in a direction inclined with respect to the direction normal to the metal plate 51 can be restrained from adhering to the flat region 52 or the second wall surface 36 of a second concave portion 35. This makes it possible to reduce the occurrence of a shadow around the first contours 42a of the through holes 25. Increasing the dimensions E1 and E2 with distance from the first center line L1 allows the flat regions 52 to have larger areas than in a case where the dimensions E1 and E2 are constant regardless of location. This makes it possible to increase the strength of the deposition mask 20, thus making it possible to restrain the deposition mask 20 from becoming damaged, for example, in shipment.

In the deposition mask 20 of the present embodiment, the non-flat coupling portions 57 are each present between two through holes 25 adjacent to each other in the second direction D2. In other words, two through holes 25 adjacent to each other in the second direction D2 are connected to each other. For this reason, a portion of the deposited material 98 having a velocity component in the second direction D2 and migrating in a direction inclined with respect to the direction normal to the metal plate 51 can be restrained from adhering to the coupling portions 57 or the second wall surfaces 36 of the second concave portions 35. This makes it possible to reduce the occurrence of a shadow around the second contours 42b of the through holes 25.

Various changes may be made to the foregoing embodiment. The following describes other embodiments with reference to the drawings as needed. In the following description and the drawings to which the following description refers, components that may be configured in the same manner as in the foregoing embodiment are assigned the same reference signs as those assigned to the corresponding components in the foregoing embodiment, and a repeated description is omitted. In a case where it is clear that a working effect that is brought about by the foregoing embodiment can also be brought about by another embodiment, a description of the working effect may be omitted.

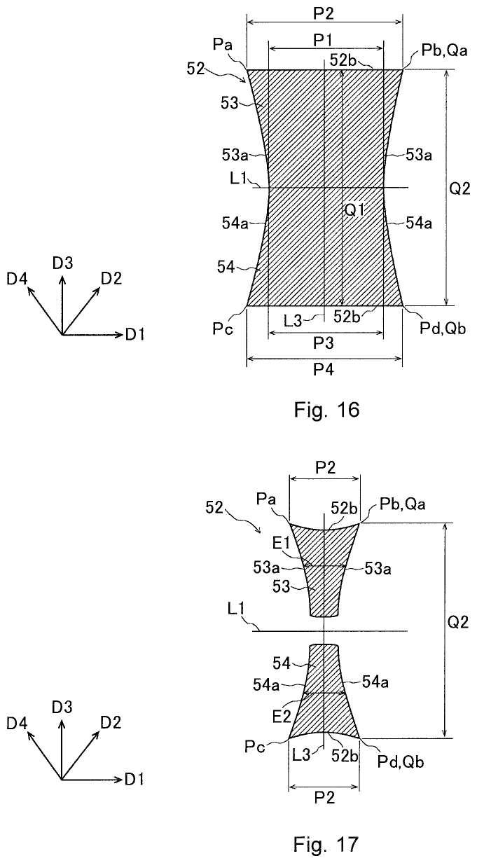

FIG. 16 is a plan view showing an example of a flat region 52 on the second surface 51b of a deposition mask 20. The foregoing embodiment has illustrated an example in which the dimension Q1 of a flat region 52 is smaller than the distance Q2 between the ends Qa and Qb of the flat region 52. However, this is not intended to impose any limitation, and as shown in FIG. 16, the dimension Q1 may be equal to the distance Q2. For example, the second contours 52b may linearly extend along the first direction D1. In this case, Q1/Q2 is 1.00.

In a deposition mask 20 including flat regions 52 each shown in FIG. 16 too, the first flat region 53 may include a portion in which the dimension E1 increases upward away from the first center line L1, as in the case of the foregoing embodiment. The second flat region 54 may include a portion in which the dimension E2 increases downward away from the first center line L1. For this reason, a portion of the deposited material 98 having a velocity component in the first direction D1 and migrating in a direction inclined with respect to the direction normal to the metal plate 51 can be restrained from adhering to the flat region 52 or the second wall surface 36 of a second concave portion 35. This makes it possible to reduce the occurrence of a shadow around the first contours 42a of the through holes 25. Increasing the respective dimensions E1 and E2 of the first and second flat regions 53 and 54 in the first direction D1 with distance from the first center line L1 allows the flat regions 52 to have larger areas than in a case where the dimensions E1 and E2 are constant regardless of location. This makes it possible to increase the strength of the deposition mask 20, thus making it possible to restrain the deposition mask 20 from becoming damaged, for example, in shipment.

FIG. 17 is a plan view showing an example of a flat region 52 on the second surface 51b of a deposition mask 20. The foregoing embodiment has illustrated an example in which the first flat region 53 and the second flat region 54 are contiguous to each other in the third direction D3. However, this is not intended to impose any limitation, and as shown in FIG. 17, the first flat region 53 and the second flat region 54 may be noncontiguous to each other in the third direction D3. That is, a non-flat region may be present between the first flat region 53 and the second flat region 54. For example, as shown in FIG. 17, a region overlapping the first center line L1 between the first flat region 53 and the second flat region 54 may be the non-flat region.

In the example shown in FIG. 17 too, the first flat region 53 may include a portion in which the dimension E1 increases upward away from the first center line L1, as in the case of the foregoing embodiment. The second flat region 54 may include a portion in which the dimension E2 increases downward away from the first center line L1.

In the example shown in FIG. 17, the second surface etching step is executed so that the first flat region 53 and the second flat region 54 are noncontiguous to each other. For example, the second surface etching step may take a longer time than in the case of the foregoing embodiment. The dimension of the second surface resist layer 62 in the first direction D1 may be made smaller than in the case of the foregoing embodiment.

In a deposition mask 20 including flat regions 52 each shown in FIG. 17 too, a portion of the deposited material 98 having a velocity component in the first direction D1 and migrating in a direction inclined with respect to the direction normal to the metal plate 51 can be restrained from adhering to the flat region 52 or the second wall surface 36 of a second concave portion 35. This makes it possible to reduce the occurrence of a shadow around the first contours 42a of the through holes 25. Increasing the dimensions E1 and E2 with distance from the first center line L1 allows the flat regions 52 to have larger areas than in a case where the dimensions E1 and E2 are constant regardless of location. This makes it possible to increase the strength of the deposition mask 20, thus making it possible to restrain the deposition mask 20 from becoming damaged, for example, in shipment.

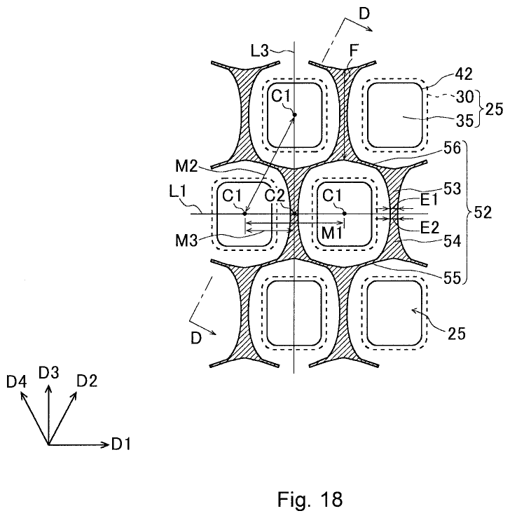

FIG. 18 is a plan view showing an example of an effective region 22 of a deposition mask 20 as seen from the second surface 51b side. The foregoing embodiment has illustrated an example in which no flat region 52 is present between two through holes 25 adjacent to each other in the second direction D2. However, this is not intended to impose any limitation, and as shown in FIG. 18, the deposition mask 20 may include third flat regions 55 each located between two through holes 25 adjacent to each other in the second direction D2. That is, two through holes 25 adjacent to each other in the second direction D2 may not be connected to each other. The deposition mask 20 may include fourth flat regions 56 each located between two through holes 25 adjacent to each other in the fourth direction D4.

In the example shown in FIG. 18 too, the first flat region 53 may include a portion in which the dimension E1 increases upward away from the first center line L1, as in the case of the foregoing embodiment. The second flat region 54 may include a portion in which the dimension E2 increases downward away from the first center line L1.

As shown in FIG. 18, the first flat region 53 and the second flat region 54 may be contiguous to each other in the third direction D3. Alternatively, although not illustrated, the first flat region 53 and the second flat region 54 may be noncontiguous to each other in the third direction D3.

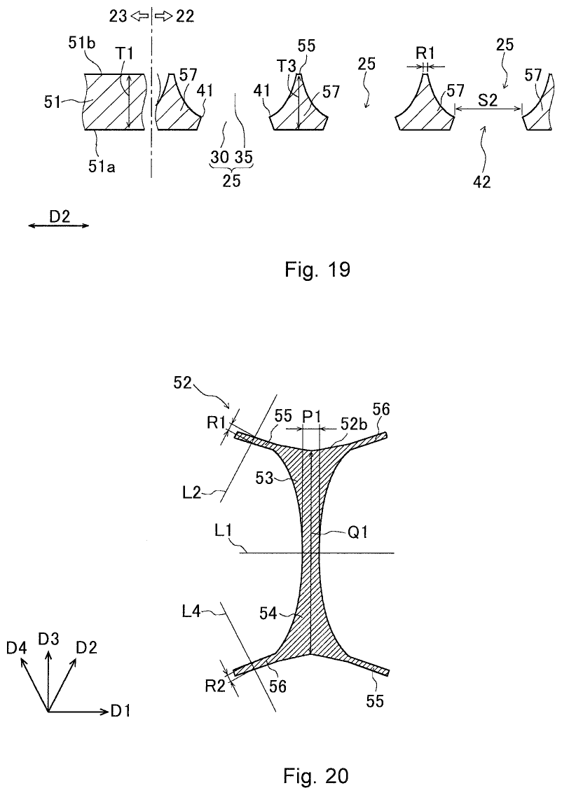

FIG. 19 is an example of a cross-sectional view of the deposition mask 20 as taken along line D-D in FIG. 18. FIG. 20 is a plan view showing a flat region 52 of FIG. 18. Each of the third flat regions 55 may extend in the second direction D2 so as to connect a first flat region 53 and a second flat region 54 that are adjacent to each other in the second direction D2. Similarly, each of the fourth flat regions 56 may extend in the fourth direction D4 so as to connect a first flat region 53 and a second flat region 54 that are adjacent to each other in the fourth direction D4.

In FIG. 20, reference sign R1 denotes a dimension in the second direction D2 of a portion of the third flat region 55 that overlaps a second center line L2. The second center line L2 is a straight line passing through the center points C1 of two through holes 25 adjacent to each other in the second direction D2. The dimension R1 of the third flat region 55 may be smaller than the dimension P1 of the first flat region 53. For this reason, a portion of the deposited material 98 having a velocity component in the second direction D2 and migrating in a direction inclined with respect to the direction normal to the metal plate 51 can be restrained from adhering to the coupling portions 57 or the second wall surfaces 36 of the second concave portions 35. This makes it possible to reduce the occurrence of a shadow around the second contours 42b of the through holes 25.

The ratio of the dimension R1 to the dimension P1 may for example be higher than or equal to 0.01, higher than or equal to 0.10, higher than or equal to 0.30, or higher than or equal to 0.45. R1/P1 may for example be lower than or equal to 0.60, lower than or equal to 0.70, lower than or equal to 0.80, or lower than or equal to 0.90. R1/P1 may fall within a range defined by a first group consisting of 0.01, 0.10, 0.30, and 0.45 and/or a second group consisting of 0.60, 0.70, 0.80, and 0.90. R1/P1 may fall within a range defined by a combination of any one of the values included in the aforementioned first group and any one of the values included in the aforementioned second group. R1/P1 may fall within a range defined by a combination of any two of the values included in the aforementioned first group. R1/P1 may fall within a range defined by a combination of any two of the values included in the aforementioned second group. R1/P1 may for example be higher than or equal to 0.01 and lower than or equal to 0.90, higher than or equal to 0.01 and lower than or equal to 0.80, higher than or equal to 0.01 and lower than or equal to 0.70, higher than or equal to 0.01 and lower than or equal to 0.60, higher than or equal to 0.01 and lower than or equal to 0.45, higher than or equal to 0.01 and lower than or equal to 0.30, higher than or equal to 0.01 and lower than or equal to 0.10, higher than or equal to 0.10 and lower than or equal to 0.90, higher than or equal to 0.10 and lower than or equal to 0.80, higher than or equal to 0.10 and lower than or equal to 0.70, higher than or equal to 0.10 and lower than or equal to 0.60, higher than or equal to 0.10 and lower than or equal to 0.45, higher than or equal to 0.10 and lower than or equal to 0.30, higher than or equal to 0.30 and lower than or equal to 0.90, higher than or equal to 0.30 and lower than or equal to 0.80, higher than or equal to 0.30 and lower than or equal to 0.70, higher than or equal to 0.30 and lower than or equal to 0.60, higher than or equal to 0.30 and lower than or equal to 0.45, higher than or equal to 0.45 and lower than or equal to 0.90, higher than or equal to 0.45 and lower than or equal to 0.80, higher than or equal to 0.45 and lower than or equal to 0.70, higher than or equal to 0.45 and lower than or equal to 0.60, higher than or equal to 0.60 and lower than or equal to 0.90, higher than or equal to 0.60 and lower than or equal to 0.80, higher than or equal to 0.60 and lower than or equal to 0.70, higher than or equal to 0.70 and lower than or equal to 0.90, higher than or equal to 0.70 and lower than or equal to 0.80, or higher than or equal to 0.80 and lower than or equal to 0.90.

In FIG. 20, reference sign R2 denotes a dimension in the fourth direction D4 of a portion of the fourth flat region 56 that overlaps a fourth center line L4. The fourth center line L4 is a straight line passing through the center points C1 of two through holes 25 adjacent to each other in the fourth direction D4. The dimension R2 of the fourth flat region 56 may be smaller than the dimension P1 of the first flat region 53. For this reason, a portion of the deposited material 98 having a velocity component in the fourth direction D4 and migrating in a direction inclined with respect to the direction normal to the metal plate 51 can be restrained from adhering to the coupling portions 57 or the second wall surfaces 36 of the second concave portions 35. This makes it possible to reduce the occurrence of a shadow around the second contours 42b of the through holes 25.

The range of numerical values of the ratio of the dimension R2 to the dimension P1 is not described, as it is similar to the range of numerical values of the ratio of the dimension R1 to the dimension P1.

In a deposition mask 20 including flat regions 52 shown in FIG. 18 too, a portion of the deposited material 98 having a velocity component in the first direction D1 and migrating in a direction inclined with respect to the direction normal to the metal plate 51 can be restrained from adhering to the flat regions 52 or the second wall surfaces 36 of the second concave portions 35. This makes it possible to reduce the occurrence of a shadow around the first contours 42a of the through holes 25. Increasing the respective dimensions E1 and E2 of the first and second flat regions 53 and 54 in the first direction D1 with distance from the first center line L1 allows the flat regions 52 to have larger areas than in a case where the dimensions E1 and E2 are constant regardless of location. This makes it possible to increase the strength of the deposition mask 20, thus making it possible to restrain the deposition mask 20 from becoming damaged, for example, in shipment.

Since the dimension R1 of the third flat region 55 is smaller than the dimension P1 of the first flat region 53, a portion of the deposited material 98 having a velocity component in the second direction D2 and migrating in a direction inclined with respect to the direction normal to the metal plate 51 can be restrained from adhering to the third flat region 55 or the second wall surface 36 of a second concave portion 35. This makes it possible to reduce the occurrence of a shadow around the first contours 42a of the through holes 25, thereby making it possible to reduce the occurrence of a shadow around the second contours 42b of the through holes 25.

The foregoing embodiment has illustrated an example in which the first surface 51a of the metal plate 51 is processed by executing the first surface etching step. However, the first surface etching step is not the only first surface processing step of processing the first surface 51a. For example, the first surface 51a may be processed by irradiating the metal plate 51 with a laser. In this case, as will be described below, the laser processing may be executed instead of the first surface etching step.

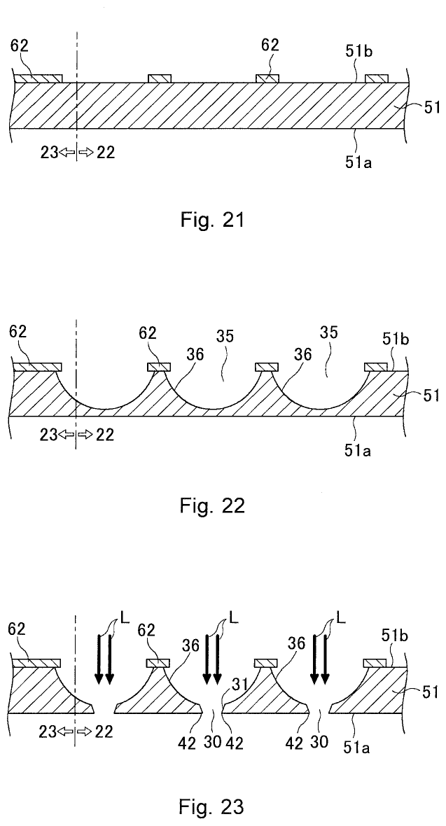

First, as shown in FIG. 21, a second surface resist layer 62 is formed on the second surface 51b of the metal plate 51, and the second surface resist layer 62 is patterned. Then, as shown in FIG. 22, the second surface etching step of etching regions on the second surface 51b of the metal plate 51 not covered with the second surface resist layer 62 is executed to form second concave portions 35 in the second surface 51b. After that, as shown in FIG. 23, a laser processing step of irradiating, with a laser L, parts of the portions of the metal plate 51 in which the second concave portions 35 have been formed. The laser processing step forms first concave portions 30 passing from the second wall surfaces 36 of the second concave portions 35 to the first surface 51a. As shown in FIG. 23, the irradiation with the laser L may be from the second surface 51b side of the metal plate 51.

In the example shown in FIGS. 21 to 23 too, forming the aforementioned flat regions 52 on the second surface 51b of the deposition mask 20 makes it possible to reduce the occurrence of a shadow around the through holes 25.

As shown in FIG. 23, the wall surfaces 31 of the first concave portions 30 formed by laser processing may be inclined so as to become gradually closer to the center points of the through holes 25 in planar view as the wall surfaces 31 extend from the second surface 51b toward the first surface 51a. In this case, ends of each of the first concave portions 30 on the first surface 51a may demarcate a through region 42 in which the opening area of the through hole 25 reaches its minimum.

### EXAMPLES

Next, the embodiment of the present disclosure is described in more concrete terms with reference to examples. However, the embodiment of the present disclosure is not limited to the following description of the examples, provided the embodiment of the present disclosure does not depart from the scope of the embodiment of the present disclosure.

### Example 1

Deposition masks 20 each including flat regions 52 each shown in FIG. 9 were fabricated. The dimensions of portions of each of the deposition masks 20 are as follows:
Dimension S1 of through region 42 in first direction D1: 30 μm
Thickness T2 of flat region 52: 25 μm
Dimension P1 of first flat region 53 overlapping first center line L1: 2.0 μm
Distance P2 between ends Pa and Pb of first flat region 53: 19 μm
Dimension Q1 of flat region 52 overlapping third center line L3: 30 μm
Distance Q2 between ends Qa and Qb of flat region 52: 35 μm

In the flat region 52 of Example 1, the dimension P1 is smaller than the distance P2, and P1/P2 is 0.11. The dimension Q1 is smaller than the distance Q2, and Q1/Q2 is 0.86.

Then, as shown in FIG. 4, the deposition masks 20 were fixed to the frame 15. Specifically, the ends 17a and 17b were welded to the frame 15 with tension applied to the deposition masks 20 in a length direction.

The deposition masks 20 welded to the frame 15 were observed with a magnifying glass. There was no damage or deformation in the deposition masks 20. Specifically, it was confirmed that there were no cracks or bends in the deposition masks 20.

Then, a deposition step of forming deposited layers by causing a deposited material 98 to adhere onto a substrate 110 was executed with the deposition masks 20. The deposited material 98 used was tris(8-quinolinolato)aluminum, which is an organic luminescence material. The substrate 110 used as a glass substrate. Conditions for the deposition step were set so that the deposited layers had thicknesses of 40 nm.

Then, the deposited layers on the substrate 110 were observed with a LEICA's optical microscope DMRX HX DC300F and a Hitachi High-Tech Corporation's coherence scanning interferometry VertScan. The area ratios V of the deposited layers were calculated based on the observations. The area ratio V of a deposited layer is the ratio of the effective area V2 of the deposited layer to the area V1 of a through region 42. Specifically, V=V2/V1. The effective area V2 is the area of a region of the deposited layer having a thickness greater than or equal to 95% of a target thickness. In a case where the target thickness is 40 nm, the effective area V2 is the area of a region of the deposition layer having a thickness of 38 nm or greater.

The area ratio V was calculated for each of the thirty deposited layers on the substrate 110. All deposited layers had area ratios V of 0.70 or higher.

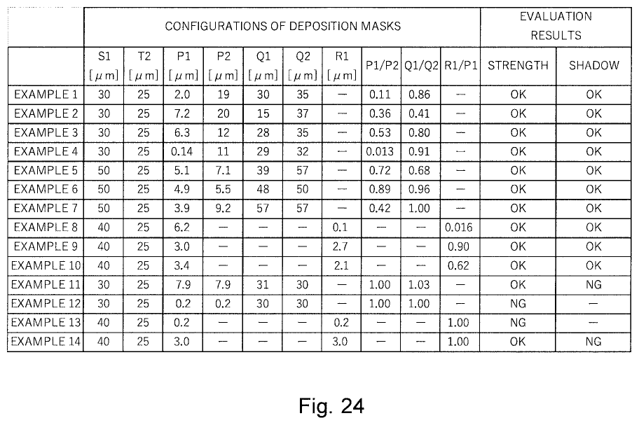

The configurations of the deposition masks 20 in Example 1 and evaluation results are shown in FIG. 24.

In column “STRENGTH” under the heading “EVALUATION RESULTS”, the word “OK” means that there was no crack or bend in a deposition mask 20 after the deposition mask 20 had been welded to the frame 15. The word “NG” means that there was a crack or a bend in a deposition mask 20 after the deposition mask 20 had been welded to the frame 15 or there had been a crack or a bend in a deposition mask 20 before the deposition mask 20 was welded to the frame 15.

In column “SHADOW” under the heading “EVALUATION RESULTS”, the word “OK” means that all of the thirty deposited layers on the substrate 110 had area ratios V of 0.70 or higher. The word “NG” means that there were deposited layers whose area ratios V were lower than 0.70.

### Examples 2 to 6

Depositions masks 20 each including flat regions 52 each shown in FIG. 9 were fabricated. The dimensions of portions of each of the deposition masks 20 of Examples 2 to 6 are shown in FIG. 24. In each of the flat regions 52 of Examples 2 to 6 too, the dimension P1 is smaller than the distance P2, as in the case of Example 1. In each of the flat regions 52 of Examples 2 to 6, P1/P2 is lower than or equal to 0.90. In each of the flat regions 52 of Examples 2 to 6 too, the dimension Q1 is smaller than the distance Q2, as in the case of Example 1.

Then, as in the case of Example 1, the deposition masks 20 of each of Examples 2 to 6 were fixed to the frame 15. There were no cracks or bends in the deposition masks 20 welded to the frame 15.

Then, as in the case of Example 1, the deposition masks 20 of each of Examples 2 to 6 were used to form deposited layers by causing the deposited material 98 to adhere onto the substrate 110. All of the thirty deposited layers on the substrate 110 had area ratios V of 0.70 or higher.

### Example 7

Deposition masks 20 each including flat regions 52 each shown in FIG. 16 were fabricated. The dimensions of portions of each of the deposition masks 20 of Example 7 are shown in FIG. 24. In each of the flat regions 52 of Example 7 too, as in the case of Example 1, the dimension P1 is smaller than the distance P2, and P1/P2 is 0.42. In each of the flat regions 52 of Example 7, Q1/Q2 is 1.00, as the dimension Q1 and the distance Q2 are equal to each other.

Then, as in the case of Example 1, the deposition masks 20 of Example 7 were fixed to the frame 15. There were no cracks or bends in the deposition masks 20 welded to the frame 15.

Then, as in the case of Example 1, the deposition masks 20 of Example 7 were used to form deposited layers by causing the deposited material 98 to adhere onto the substrate 110. All of the thirty deposited layers on the substrate 110 had area ratios V of 0.70 or higher.

### Examples 8 to 10

Deposition masks 20 each including flat regions 52 each shown in FIG. 20 were fabricated. The dimensions of portions of each of the deposition masks 20 of Examples 8 to 10 are shown in FIG. 24. In each of the flat regions 52 of Examples 8 to 10, the dimension R1 is smaller than the dimension P1, and R1/P1 is lower than or equal to 0.90.

Then, as in the case of Example 1, the deposition masks 20 of each of Examples 8 to 10 were fixed to the frame 15. There were no cracks or bends in the deposition masks 20 welded to the frame 15.

Then, as in the case of Example 1, the deposition masks 20 of each of Examples 8 to 10 were used to form deposited layers by causing the deposited material 98 to adhere onto the substrate 110. All of the thirty deposited layers on the substrate 110 had area ratios V of 0.70 or higher. Examples 11 and 12

Deposition masks 20 each including flat regions 52 each shown in FIG. 9 were fabricated. The dimensions of portions of each of the deposition masks 20 of Examples 11 and 12 are shown in FIG. 24. In each of the flat regions 52 of Examples 11 and 12, P1/P2 is 1.00, as the dimension P1 and the distance P2 are equal to each other. The deposition masks 20 of Example 12 were visually checked, with the result that cracks and bends were found in some of the deposition masks 20.

Then, as in the case of Example 1, the deposition masks 20 of Example 11 were fixed to the frame 15. There were no cracks or bends in the deposition masks 20 welded to the frame 15.

Then, as in the case of Example 1, the deposition masks 20 of Example 11 were used to form deposited layers by causing the deposited material 98 to adhere onto the substrate 110. Some of the thirty deposited layers on the substrate 110 had area ratios V lower than 0.70.

An evaluation of a shadow was not made for the deposition masks 20 of Example 12.

### Examples 13 and 14

Deposition masks 20 each including flat regions 52 each shown in FIG. 20 were fabricated. The dimensions of portions of each of the deposition masks 20 of Examples 13 and 14 are shown in FIG. 24. In each of the flat regions 52 of Examples 13 and 14, R1/P1 is 1.00, as the dimension P1 and the dimension R1 are equal to each other. The deposition masks 20 of Example 13 were visually checked, with the result that cracks and bends were found in some of the deposition masks 20.

Then, as in the case of Example 1, the deposition masks 20 of Example 14 were fixed to the frame 15. There were no cracks or bends in the deposition masks 20 welded to the frame 15.

Then, as in the case of Example 1, the deposition masks 20 of Example 14 were used to form deposited layers by causing the deposited material 98 to adhere onto the substrate 110. Some of the thirty deposited layers on the substrate 110 had area ratios V lower than 0.70.

An evaluation of a shadow was not made for the deposition masks 20 of Example 13.

What is claimed is:

1. A deposition mask including two or more through holes, the deposition mask comprising:
a metal plate including a first surface and a second surface located opposite the first surface;
the through holes each bored through the metal plate from the first surface to the second surface; and
a flat region located between two of the through holes adjacent to each other in a case where the deposition mask is seen from the second surface side,
wherein
the through holes are arrayed in a staggered arrangement in a first direction and a second direction in planar view,
the flat region includes a first flat region located at a first side of a first center line and a second flat region located at a second side of the first center line,
the first center line passes through center points of two of the through holes adjacent to each other in the first direction,
the first flat region includes a portion in which a dimension of the first flat region in the first direction increases away from the first center line, and
the second flat region includes a portion in which a dimension of the second flat region in the first direction increases away from the first center line.

2. The deposition mask according to claim 1, wherein the first flat region and the second flat region are contiguous to each other.

3. The deposition mask according to claim 1, wherein the first flat region and the second flat region are noncontiguous to each other.

4. The deposition mask according to claim 1, wherein in a case where the deposition mask is seen from the second surface side, two of the through holes adjacent to each other in the second direction are connected to each other.

5. The deposition mask according to claim 1, further comprising a third flat region located between two of the through holes adjacent to each other in the second direction in a case where the deposition mask is seen from the second surface side.

6. The deposition mask according to claim 1, wherein
the first flat region and the second flat region are contiguous to each other, and in a case where the deposition mask is seen from the second surface side, two of the through holes adjacent to each other in the second direction are connected to each other, and
a dimension in the first direction of a portion of the first flat region that overlaps the first center line is 0.90 time or less as great as a distance in the first direction between ends of two contours of the first flat region, the two contours facing the through holes in the first direction.

7. The deposition mask according to claim 1, wherein
the first flat region and the second flat region are contiguous to each other, and in a case where the deposition mask is seen from the second surface side, two of the through holes adjacent to each other in the second direction are connected to each other,
a dimension in a third direction of a portion of the flat region that overlaps a third center line is 1.00 time or less as great as a distance in the third direction between ends of two contours of the flat region, the two contours facing the through holes in the third direction,
the third direction is orthogonal to the first direction, and
the third center line passes through center points of two of the through holes adjacent to each other in the first direction and extends in the third direction.

8. The deposition mask according to claim 1, wherein
each of the through holes includes a first concave portion including a first wall surface located at the first surface and a second concave portion including a second wall surface located at the second surface, the second concave portion being connected to the first concave portion, and
the second wall surface includes a portion that becomes gradually closer to a center point of the through hole as the portion extends from the second surface toward the first surface.

9. The deposition mask according to claim 1, wherein the flat region exhibits a pixel value greater than or equal to a reference value in a case where the deposition mask is observed with a laser microscope from the second surface side.

10. The deposition mask according to claim 1, wherein a thickness of the flat region is equal to a thickness of the metal plate.

11. The deposition mask according to claim 1, wherein the metal plate has a thickness of 50 μm or less.

12. A method for manufacturing a deposition mask including two or more through holes, the method comprising:
a first surface processing step of forming, in a first surface of a metal plate, a first concave portion including a first wall surface; and
a second surface etching step of etching a region of a second surface of the metal plate with an etchant and forming, in the second surface, a second concave portion including a second wall surface, the second surface being located opposite the first surface, the region being not covered with a second surface resist layer,
wherein
each of the through holes includes the first concave portion and the second concave portion, the second concave portion being connected to the first concave portion,
the second surface etching step is executed so that a flat region remains between two of the through holes adjacent to each other in a case where the deposition mask in seen from the second surface side,
the through holes are arrayed in a staggered arrangement in a first direction and a second direction in planar view,
the flat region includes, between two of the through holes adjacent to each other in the first direction, a first flat region located at a first side of a first center line and a second flat region located at a second side of the first center line,
the first center line passes through center points of two of the through holes adjacent to each other in the first direction,
the first flat region includes a portion in which a dimension of the first flat region in the first direction increases away from the first center line, and
the second flat region includes a portion in which a dimension of the second flat region in the first direction increases away from the first center line.

13. The method according to claim 12, wherein the second surface etching step is executed so that the first flat region and the second flat region are contiguous to each other.

14. The method according to claim 12, wherein the second surface etching step is executed so that the first flat region and the second flat region are noncontiguous to each other.

15. The method according to claim 12, wherein the second surface etching step is executed so that in a case where the deposition mask is seen from the second surface side, two of the through holes adjacent to each other in the second direction are connected to each other.

16. The method according to claim 12, wherein the second surface etching step is executed so that in a case where the deposition mask is seen from the second surface side, two of the through holes adjacent to each other in the second direction are not connected to each other.

17. The method according to claim 12, wherein
the second surface resist layer includes a first region corresponding to the first flat region and a second region corresponding to the second flat region,
the first region includes a portion in which a dimension of the first region in the first direction increases away from the first center line, and
the second region includes a portion in which a dimension of the second region in the first direction increases away from the first center line.

18. The method according to claim 12, wherein the flat region exhibits a pixel value greater than or equal to a reference value in a case where the deposition mask is observed with a laser microscope from the second surface side.

19. The method according to claim 12, wherein the metal plate has a thickness of 50 μm or less.
